(19) United States
(12) Patent Application Publication
(10) Pub. No.: US 2024/0224587 A1
(43) Pub. Date: Jul. 4, 2024

(54) ORGANIC LIGHT EMITTING DISPLAY APPARATUS

(71) Applicant: LG Display Co., Ltd., Seoul (KR)

(72) Inventors: TaeJoon SONG, Paju-si (KR); JungSik JO, Goyang-si (KR); ChulHo KIM, Incheon (KR); WooChan CHO, Paju-si (KR)

(73) Assignee: LG Display Co., Ltd., Seoul (KR)

(21) Appl. No.: 18/383,404

(22) Filed: Oct. 24, 2023

(30) Foreign Application Priority Data
Dec. 30, 2022 (KR) 10-2022-0191131

(51) Int. Cl. H10K 59/121; G09G 3/3225; H10K 59/40; H10K 59/65

(52) U.S. Cl. CPC H10K 59/121; G09G 3/3225; H10K 59/40; H10K 59/65; G09G 2300/0819; G09G 2300/0842

(57) ABSTRACT

An organic light emitting display apparatus includes a substrate including a first display area having emission areas and transmissive areas, and a second display area adjacent to the first display area. The organic light emitting display further includes a plurality of sub-pixels disposed in the first display area, and a plurality of transistors electrically connected to the plurality of sub-pixels. The plurality of sub-pixels include a plurality of first sub-pixels disposed in the emission areas of the first display area and having a structure in which a plurality of light emitting stacks configured to emit light of different colors are stacked.

### CROSS-REFERENCE TO RELATED APPLICATIONS

This application claims priority to Korean Patent Application No. 10-2022-0191131 filed on Dec. 30, 2022, in the Republic of Korea, the entire contents of which are hereby expressly incorporated by reference into the present application.

### BACKGROUND

### Technical Field

The present disclosure relates to an organic light emitting display apparatus, and more particularly, to provide an organic light emitting display apparatus having an improved transmittance.

### Discussion of the Related Art

The field of organic light emitting display apparatuses for visually displaying an electrical information signal has rapidly advanced. The development of various organic light emitting display apparatuses having excellent performance in terms of thinness, lightness, and low power consumption, is being conducted correspondingly.

Representative organic light emitting display apparatuses can include a liquid crystal display (LCD), a field emission display (FED), an electro-wetting display (EWD), an organic light emitting display (OLED), and the like.

An electroluminescent organic light-emitting display apparatus represented by an organic light emitting display apparatus is a self-emitting organic light emitting display apparatus, and can be manufactured to be light and thin since it does not require a separate light source, unlike a liquid crystal display having a separate light source.

In addition, the electroluminescent organic light-emitting display apparatus has advantages in terms of power consumption due to a low voltage driving, and is excellent in terms of a color implementation, a response speed, a viewing angle, and a contrast ratio (CR). Therefore, electroluminescent organic light-emitting display apparatuses are expected to be utilized in various fields.

Recently, multimedia functions of mobile terminals have been improved. For example, organic light emitting display apparatuses in which an optical electronic device such as a camera or a sensor is built into a front surface thereof have been developed. However, a camera or sensor disposed on the front surface of the organic light emitting display apparatus can limit a screen design.

As such, in order to reduce a space occupied by the camera or sensor on the front surface of the organic light emitting display apparatus, a design including a notch or punch hole can be applied, but a screen size can still be limited, so it is not easy to implement a full-screen display.

In order to implement the full-screen display, a method of providing an area in which low-resolution pixels are disposed on a screen of an organic light emitting display apparatus and disposing a camera and/or various sensors in the area where the low-resolution pixels are disposed has been proposed.

### SUMMARY OF THE DISCLOSURE

An object to be achieved by the present disclosure is to provide an organic light emitting display apparatus having an improved transmittance in a transmissive area where an optical electronic device such as a camera or a sensor is disposed.

Objects of the present disclosure are not limited to the above-mentioned objects, and other objects, which are not mentioned above, can be clearly understood by those skilled in the art from the following descriptions.

An organic light emitting display apparatus according to an exemplary embodiment of the present disclosure includes a substrate including a first display area having emission areas and transmissive areas, and a second display area surrounding the first display area; a plurality of sub-pixels disposed in the first display area; and a plurality of transistors disposed on the substrate and electrically connected to the plurality of sub-pixels, wherein the number of sub-pixels per unit area in the first display area is less than the number of sub-pixels per unit area in the second display area, and the plurality of sub-pixels include a plurality of first sub-pixels disposed in the emission areas of the first display area and having a structure in which a plurality of light emitting stacks emitting light of different colors are stacked.

Other detailed matters of the exemplary embodiments are included in the detailed description and the drawings.

According to an aspect of the present disclosure, by disposing a camera or sensor at a lower end of a light emitting element or touch electrode in a display area, a display or touch on an upper portion thereof cannot be disconnected.

In an aspect of the present disclosure, a transparent area in which opaque components such as metal electrodes are not placed can be located in an area that overlaps an area where a camera or sensor is disposed. Accordingly, light transmittance in the area where a camera or sensor is disposed is improved, so that visibility of an organic light emitting display apparatus can be improved.

In the present disclosure, a smaller number of sub-pixels are disposed in an optical area including a transmissive area than in a normal area, while the sub-pixels having a structure in which a plurality of light emitting stacks are stacked are disposed, so that a transmissive surface area can be expanded.

The effects according to various embodiments of the present disclosure are not limited to the contents exemplified above, and more various effects are included in the present specification.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIGS. 1A to 1D are schematic plan views of an organic light emitting display apparatus according to an exemplary embodiment of the present disclosure.

FIG. 2 is a system configuration diagram of the organic light emitting display apparatus according to an exemplary embodiment of the present disclosure.

FIG. 3 is an equivalent circuit diagram of a sub-pixel in a display panel according to an exemplary embodiment of the present disclosure.

FIG. 4 is a view illustrating an example in which sub-pixels are disposed in a display area of the display panel according to an exemplary embodiment of the present disclosure.

FIG. 5A is a view illustrating an example in which signal lines are disposed in each of a first optical area and a normal area in the display panel according to an exemplary embodiment of the present disclosure.

FIG. 5B is a view illustrating an example in which signal lines are disposed in each of a second optical area and a normal area in the display panel according to an exemplary embodiment of the present disclosure.

FIG. 6 is a schematic enlarged plan view illustrating a normal area of the display panel according to an exemplary embodiment of the present disclosure.

FIG. 7 is a cross-sectional view taken along line I-I′ of FIG. 6.

FIG. 8 is a schematic enlarged plan view illustrating a first optical area of the display panel according to an exemplary embodiment of the present disclosure.

FIG. 9 is a cross-sectional view taken along line II-II′ of FIG. 8.

FIG. 10A is a schematic enlarged cross-sectional view of a structure of a sub-pixel SPB illustrated in area B of FIG. 9.

FIG. 10B is a schematic enlarged cross-sectional view of a structure of a sub-pixel SPRG of FIG. 8.

FIG. 11 is a cross-sectional view illustrating another example of a structure of a pixel SPB in the first optical area of the display panel according to an exemplary embodiment of the present disclosure.

FIG. 12 is an enlarged plan view of a first optical area in a display panel of an organic light emitting display apparatus according to another exemplary embodiment of the present disclosure.

FIG. 13 is an enlarged plan view of area Z of FIG. 12.

FIG. 14 is a schematic enlarged plan view illustrating area A of FIG. 8.

FIG. 15 is a cross-sectional view taken along line III-III′ of FIG. 14.

FIG. 16 is a cross-sectional view taken along line IV-IV′ of FIG. 14.

### DETAILED DESCRIPTION OF EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “comprising,” “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “over”, “below”, “under”, “adjacent”, and “next”, one or more parts can be positioned between the two parts unless the terms are used with the term “immediately” or “directly” is not used.

When an element or layer is disposed “on”, “above”, or “over” another element or layer, one or more other layers or elements can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The term “exemplary” is used to mean an example, and is interchangeably used with the term “example”. Further, embodiments are example embodiments and aspects are example aspects. Any implementation described herein as an “example” is not necessarily to be construed as preferred or advantageous over other implementations.

The features of various embodiments of the present disclosure can be partially or entirely adhered to or combined with each other and can be interlocked and operated in technically various ways, and the embodiments can be carried out independently of or in association with each other.

Hereinafter, an organic light emitting display apparatus according to exemplary embodiments of the present disclosure will be described in detail with reference to accompanying drawings. All the components of each organic light emitting display apparatus according to all embodiments of the present disclosure are operatively coupled and configured.

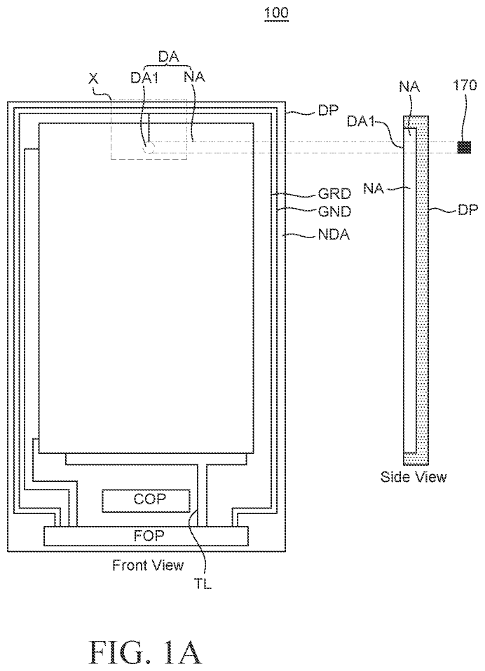

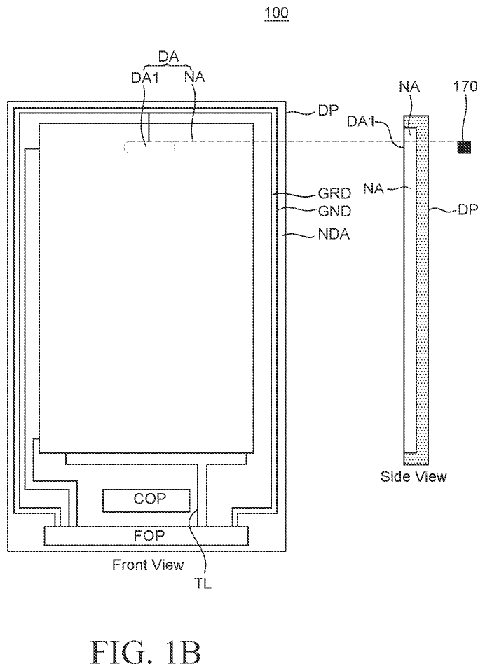

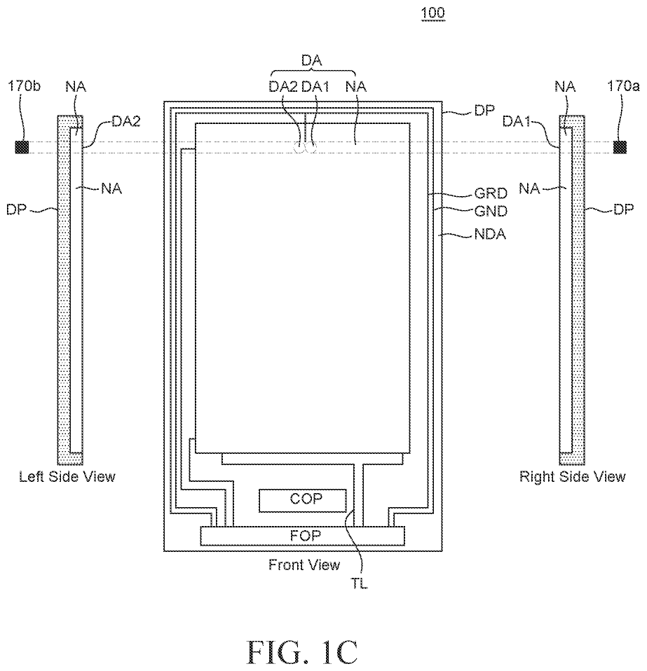

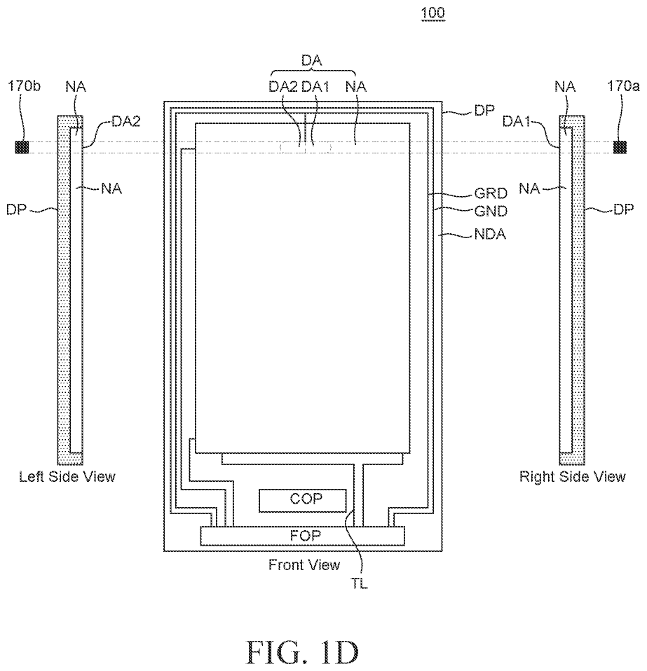

FIGS. 1A to 1D are schematic plan views of an organic light emitting display apparatus according to an exemplary embodiment of the present disclosure.

Referring to FIGS. 1A to 1D, an organic light emitting display apparatus 100 according to an exemplary embodiment of the present disclosure can include a display panel DP for displaying an image and one or more optical electronic devices 170, 170a, and 170b. The optical electronic devices 170, 170a, and 170b can include a light receiving device that receives light, such as a camera or a sensor.

The display panel DP is a panel for displaying an image to a user.

The display panel DP can include a display element for displaying an image, a driving element for driving the display element, and lines for transmitting various signals to the display element and the driving element. The display element can be defined differently depending on a type of display panel DP. For example, when the display panel DP is an organic light emitting display panel, the display element can be an organic light emitting element including an anode, a light emitting layer, and a cathode. Also, the organic light emitting display apparatus 100 according to an exemplary embodiment of the present disclosure can be a flexible organic light emitting display apparatus.

Meanwhile, the display panel DP can be configured to include a substrate and a plurality of insulating layers, a transistor layer, and a light emitting element layer on the substrate. The display panel DP can include a plurality of sub-pixels to display an image and various signal lines for driving the plurality of sub-pixels. The signal lines can include a plurality of data lines, a plurality of gate lines, a plurality of power lines, and the like. In this case, each of the plurality of sub-pixels can include a transistor located on the transistor layer and a light emitting element located on the light emitting element layer.

The display panel DP can include a display area DA (e.g., active area) where an image is displayed and a non-display area NDA (e.g., non-active area) where an image is not displayed.

The plurality of sub-pixels constituting a plurality of pixels and circuits for driving the plurality of sub-pixels can be disposed in the display area DA. The plurality of sub-pixels are minimum units constituting the display area DA, and the display element can be disposed in each of the plurality of sub-pixels, and the plurality of sub-pixels can constitute the pixels. For example, the organic light emitting element including the anode, the light emitting layer, and the cathode can be disposed in each of the plurality of sub-pixels, but the present disclosure is not limited thereto. In addition, the circuit for driving the plurality of sub-pixels can include driving elements and lines. For example, the circuit can include a thin film transistor, a storage capacitor, gate lines, data lines, and the like, but the present disclosure is not limited thereto.

The non-display area NDA can be bent and is not visible from the front or can be covered by a case, and the non-display area NDA is also referred to as or can include a bezel area. The non-display area NDA can include other area(s) such as a pad area, etc.

In the non-display area NDA, various lines and circuits for driving the organic light emitting elements of the display area DA can be disposed. For example, driver integrated circuit (ICs) such as a gate driver IC and a data driver IC, a gate in panel (GIP) line, and link lines for transmitting signals to the plurality of sub-pixels and circuits of the display area DA, and the like can be disposed in the non-display area NDA, but the present disclosure is not limited thereto. Particularly, FIGS. 1A to 1D illustrate that the non-display area NDA surrounds the display area DA having a rectangular shape, but shapes and arrangements of the display area DA and the non-display area NDA are not limited to examples illustrated in FIGS. 1A to 1D. For instance, the display area DA and the non-display area NDA can have shapes suitable for a design of an electronic device in which the organic light emitting display apparatus 100 is mounted. For example, an exemplary shape of the display area DA can be a pentagonal shape, a hexagonal shape, a circular shape, or an elliptical shape. Further, the non-display area NDA can surround the display area DA entirely or in part only. As a variation, there can be more than one display area DA and/or non-display area NDA.

Various lines and circuits for driving organic light emitting elements in the display area DA can be disposed in the non-display area NDA. For example, a driver IC such as a gate driver IC or a data driver IC, link lines, gate-in-panel (GIP) lines, and ground lines GND and GRD for transmitting signals to the plurality of sub-pixels and circuits can be disposed in the non-display area NDA, but the present disclosure is not limited thereto.

For example, the non-display area NDA can include the ground line GND that is disposed to surround the display area DA and applies a common voltage to the sub-pixels. For example, one or more ground lines GND can be formed, and if two or more ground lines GND are formed, the ground line located closer to the display area DA can be called an internal ground line GRD.

Additionally, the display device 100 can include a touch sensing unit including a plurality of touch electrodes. A touch routing line TL that transmits touch signals can be disposed on the plurality of touch electrodes.

The organic light emitting display apparatus 100 can further include various additional elements for generating various signals or driving the pixels in the display area DA. The additional elements for driving the pixels can include an inverter circuit, a multiplexer, an electrostatic discharge (ESD) circuit, and the like. In addition, the organic light emitting display apparatus 100 can also include additional elements related to functions other than pixel driving. For example, the organic light emitting display apparatus 100 can further include additional elements for providing a touch sensing function, a user authentication function (e.g., fingerprint recognition), a multi-level pressure sensing function, a tactile feedback function, and the like. The additional elements aforementioned can be located in the non-display area NDA and/or an external circuit connected to a connection interface.

For example, the non-display area NDA of the organic light emitting display apparatus 100 can include a pad area. In the pad area, pads connected to various signal lines or printed circuit boards are disposed. For example, a bending area can be further included between the display area DA and the pad area in the non-display area NDA. The bending area can be bent so that the pad area can be located on a rear surface of the display panel DP, but the present disclosure is not limited to thereto.

The pad area can include an integrated circuit bonding pad area COP which is disposed in the non-display area NDA and to which a driver integrated circuit DIC is bonded and a film bonding pad area FOP which is disposed in the non-display area NDA and to which a flexible printed circuit is bonded. In this case, the integrated circuit bonding pad area COP can be located closer to the display area DA compared to the film bonding pad area FOP.

Referring to FIGS. 1A to 1D, in the organic light emitting display apparatus 100 according to exemplary embodiments of the present disclosure, the one or more optical electronic devices 170, 170a, and 170b can be electronic components located under (on an opposite side of a viewing surface of) the display panel DP.

Light can enter a front surface (the viewing surface) of the display panel DP, pass through the display panel DP, and be transmitted to the one or more optical electronic devices 170, 170a, and 170b located under (on the opposite side of the viewing surface of) the display panel DP.

The one or more optical electronic devices 170, 170a, and 170b can be devices that receive the light transmitted through the display panel DP and perform predetermined functions according to the received light. For example, the optical electronic devices 170, 170a, and 170b can include one or more of capturing devices such as a camera (an image sensor) and the like or detection sensors such as a proximity sensor and an illumination sensor.

Referring to FIGS. 1A to 1D, in the organic light emitting display apparatus 100 according to exemplary embodiments of the present disclosure, the display area DA can include a first display area including one or more optical areas DA1 and DA2, and a second display area which can be referred to as a normal area NA.

The one or more optical areas DA1 and DA2 can be areas overlapping the one or more optical electronic devices 170, 170a and 170b.

According to an example of FIG. 1A, the display area DA can include the normal area NA (second display area) and a first optical area DA1. Here, at least a portion of the first optical area DA1 can overlap a first optical electronic device 170.

Although FIG. 1A illustrates a structure in which the first optical area DA1 has a circular shape, the shape of the first optical area DA1 according to the exemplary embodiment of the present disclosure is not limited thereto. For example, as illustrated in FIG. 1B, the first optical area DA1 can have an octagonal shape, and can also have various polygonal shapes.

According to an example of FIG. 1C, the display area DA can include a normal area NA, a first optical area DA1 and a second optical area DA2. In the example of FIG. 1C, the normal area NA can exist between the first optical area DA1 and the second optical area DA2. Here, at least a portion of the first optical area DA1 can overlap a first optical electronic device 170a, and at least a portion of the second optical area DA2 can overlap a second optical electronic device 170b.

According to an example of FIG. 1D, the display area DA can include a normal area NA, a first optical area DA1 and a second optical area DA2. In the example of FIG. 1D, the normal area NA does not exist between the first optical area DA1 and the second optical area DA2. For example, the first optical area DA1 and the second optical area DA2 can contact each other. Here, at least a portion of the first optical area DA1 can overlap the first optical electronic device 170a, and at least a portion of the second optical area DA2 can overlap the second optical electronic device 170b.

The one or more optical areas DA1 and DA2 should have both an image display structure and a light-transmissive structure. For example, since the one or more optical areas DA1 and DA2 are parts of the display area DA, the sub-pixels for displaying images should be disposed in the one or more optical areas DA1 and DA2. The light-transmissive structure for transmitting light to the one or more optical electronic devices 170, 170a, and 170b should be formed in the one or more optical areas DA1 and DA2.

The one or more optical electronic devices 170, 170a, and 170b are devices that need to receive light, but are located behind the display panel DP (under the display panel DP, on the opposite side of the viewing surface) and receive light transmitted through the display panel DP. In this case, the one or more optical electronic devices 170, 170a, and 170b are not exposed to the front surface (the viewing surface) of the display panel DP. Therefore, when a user sees a front surface of the organic light emitting display apparatus 100, the optical electronic devices 170, 170a, and 170b are not visible to the user.

For example, the first optical electronic devices 170 and 170a can be cameras, and the second optical electronic device 170b can be a detection sensor such as a proximity sensor or an illuminance sensor. For example, the detection sensor can be an infrared sensor that detects infrared rays. Conversely, the first optical electronic devices 170 and 170a can be detection sensors, and the second optical electronic device 170b can be a camera.

Hereinafter, for convenience of explanation, it is exemplified that the first optical electronic devices 170 and 170a are cameras and the second optical electronic device 170b is a detection sensor. Here, the camera can be a camera lens or an image sensor.

When the first optical electronic devices 170 and 170a are cameras, they are located behind (under) the display panel DP, but can be front cameras that captures an image in a front direction of the display panel DP. Accordingly, the user can capture an image through the camera invisible to the viewing surface while looking the viewing surface of the display panel DP.

The normal area NA and the one or more optical areas DA1 and DA2 included in the display area DA are areas capable of displaying an image. However, the normal area NA is an area where it is unnecessary to form the light-transmissive structure therein, and the one or more optical areas DA1 and DA2 are areas where it is necessary to form the light-transmissive structure therein. Accordingly, the one or more optical areas DA1 and DA2 should have a transmittance greater than or equal to a certain level, and the normal area NA can have no light transmittance or a lower transmittance lower than the certain level.

For example, the one or more optical areas DA1 and DA2 and the normal area NA can differ from each other in terms of resolution, a sub-pixel arrangement structure, the number of the sub-pixels per unit area, an electrode structure, a line structure, an electrode arrangement structure, or a line arrangement structure.

For example, the number of the sub-pixels per unit area in the one or more optical areas DA1 and DA2 can be smaller than the number of the sub-pixels per unit area in the normal area NA. For example, the resolution of the one or more optical areas DA1 and DA2 can be lower than that of the normal area NA. In this case, the number of the sub-pixels per unit area is a unit for measuring the resolution, and can also be referred to as PPI (pixels per inch), which means the number of pixels in one inch.

For example, the number of the sub-pixels per unit area in the first optical area DA1 can be smaller than the number of the sub-pixels per unit area in the normal area NA. Also, the number of the sub-pixels per unit area in the second optical area DA2 can be greater than or equal to the number of the sub-pixels per unit area in the first optical area DA1.

The first optical area DA1 can be variously shaped such as having a circular, elliptical, quadrangular, hexagonal, or octagonal shape. The second optical area DA2 can be variously shaped such as having a circular, elliptical, quadrangular, hexagonal, or octagonal shape. The first optical area DA1 and the second optical area DA2 can have the same shape or different shapes.

Referring to FIG. 1C, when the first optical area DA1 and the second optical area DA2 are in contact with each other, the entire optical area including the first optical area DA1 and the second optical area DA2 can also be variously shaped such as having a circular, elliptical, quadrangular, hexagonal, or octagonal shape.

Hereinafter, it is exemplified that each of the first optical area DA1 and the second optical area DA2 is circular, for convenience of explanation.

In the organic light emitting display apparatus 100 according to an exemplary embodiment of the present disclosure, when the first optical electronic devices 170 and 170a that are not exposed to the outside and hidden under the display panel DP are cameras, the organic light emitting display apparatus 100 according to an exemplary embodiment of the present disclosure can be referred to as a display apparatus to which an under-display camera (UDC) technology is applied.

According to this, in the case of the organic light emitting display apparatus 100 according to an exemplary embodiment of the present disclosure, since a camera hole or a notch for camera exposure does not need to be formed in the display panel DP, an area of the display area DA is not reduced. Accordingly, since it is unnecessary to form a camera hole or a notch for camera exposure in the display panel DP, the size of a bezel area can be reduced and design restrictions can be removed, so that a degree of freedom in design can increase.

In the organic light emitting display apparatus 100 according to an exemplary embodiment of the present disclosure, although the one or more optical electronic devices 170, 170a, and 170a are located and hidden behind the display panel DP, the one or more optical electronic devices 170, 170a, and 170a should able to normally receive light and normally perform predetermined functions.

In addition, in the organic light emitting display apparatus 100 according to an exemplary embodiment of the present disclosure, although the one or more optical electronic devices 170, 170a, and 170b are located and hidden behind the display panel DP and disposed to overlap the display area DA, it should be possible to normally display an image in the one or more optical areas DA1 and DA2 overlapping the one or more optical electronic devices 170, 170a, and 170b in the display area DA.

Accordingly, the organic light emitting display apparatus 100 according to an exemplary embodiment of the present disclosure can have a structure capable of improving transmittances of the first optical area DA1 and the second optical area DA2 that overlap the optical electronic devices 170, 170a, and 170b.

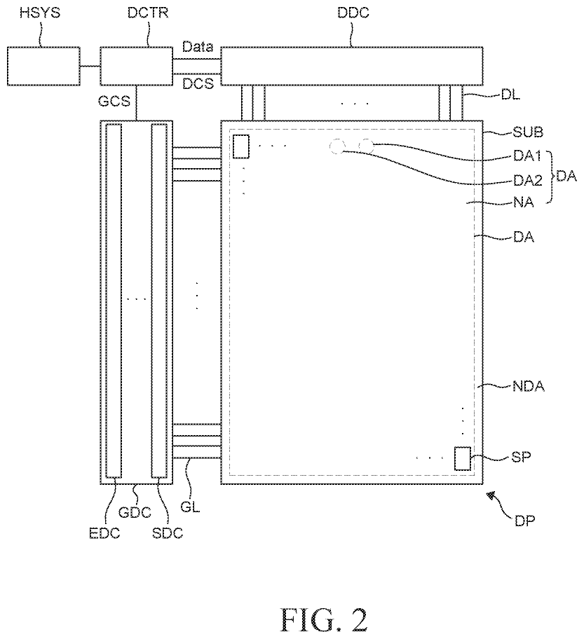

FIG. 2 is a system configuration diagram of the organic light emitting display apparatus according to an exemplary embodiment of the present disclosure.

Referring to FIG. 2, the organic light emitting display apparatus 100 can include the display panel DP and a display driving circuit as components for displaying an image. The display driving circuit is a circuit for driving the display panel DP, and can include a data driving circuit DDC, a gate driving circuit GDC, a display controller DCTR, and the like.

The display panel DP can include the display area DA where an image is displayed and the non-display area NDA where an image is not displayed. The non-display area NDA can be an area outside the display area DA, and can also be referred to as a bezel area. An entirety or part of the non-display area NDA can be an area visible from the front surface of the organic light emitting display apparatus 100 or an area that is bent and not visible from the front surface of the organic light emitting display apparatus 100.

The display panel DP can include a substrate SUB and a plurality of sub-pixels SP disposed on the substrate SUB. Also, the display panel DP can further include various types of signal lines to drive the plurality of sub-pixels SP.

The organic light emitting display apparatus 100 according to exemplary embodiments of the present disclosure can be a self-emitting organic light emitting display apparatus in which the display panel DP itself emits light, and each of the plurality of sub-pixels SP can include a light emitting element.

For example, the organic light emitting display apparatus 100 according to exemplary embodiments of the present disclosure can be an organic light emitting display apparatus in which the light emitting element is implemented with an organic light emitting diode (OLED). For another example, the organic light emitting display apparatus 100 according to exemplary embodiments of the present disclosure can be an inorganic light emitting display apparatus in which the light emitting element is implemented with an inorganic-based light emitting diode. As another example, the organic light emitting display apparatus 100 according to exemplary embodiments of the present disclosure can be a quantum dot organic light emitting display apparatus in which the light emitting element is implemented with quantum dots, which are semiconductor crystals emitting light itself.

A structure of each of the plurality of sub-pixels SP can vary according to a type of the organic light emitting display apparatus 100. For example, when the organic light emitting display apparatus 100 is a self-emitting organic light emitting display apparatus in which the sub-pixels SP emit light by themselves, each of the sub-pixels SP can include the light emitting element emitting light itself, one or more transistors, and one or more capacitors.

The various types of signal lines can include a plurality of data lines DL for transmitting data signals (also referred to as data voltages or video signals), a plurality of gate lines GL for transmitting gate signals (also referred to as scan signals), and the like.

The plurality of data lines DL and the plurality of gate lines GL can cross each other. Each of the plurality of data lines DL can be disposed to extend in a first direction. Each of the plurality of gate lines GL can be disposed to extend in a second direction. Here, the first direction can be a column direction and the second direction can be a row direction. Alternatively, the first direction can be the row direction and the second direction can be the column direction. As a variation, the first and second directions cross each other and the cross-angle can be at 90 degrees or less than 90 degrees.

The data driving circuit DDC is a circuit for driving the plurality of data lines DL, and can output data signals to the plurality of data lines DL. The gate driving circuit GDC is a circuit for driving the plurality of gate lines GL, and can output gate signals to the plurality of gate lines GL.

The display controller DCTR is a device for controlling the data driving circuit DDC and the gate driving circuit GDC and can control a driving timing of the plurality of data lines DL and a driving timing of the plurality of gate lines GL.

The display controller DCTR can supply data driving control signals DCS to the data driving circuit DDC to control the data driving circuit DDC, and supply gate driving control signals GCS to the gate driving circuit GDC to control the gate driving circuit GDC.

The display controller DCTR can receive input image data from a host system HSYS and supply image data Data to the data driving circuit DDC based on the input image data.

The data driving circuit DDC can supply data signals to the plurality of data lines DL according to driving timing control of the display controller DCTR. The data driving circuit DDC can receive the image data Data in a digital format from the display controller DCTR, convert the received image data Data into data signals in an analog format, and output the signals to the plurality of data lines DL.

The gate driving circuit GDC can supply gate signals to the plurality of gate lines GL according to timing control of the display controller DCTR. The gate driving circuit GDC can be supplied with a first gate voltage corresponding to a turn-on level voltage and a second gate voltage corresponding to a turn-off level voltage together with various gate driving control signals GCS to thereby generate the gate signals and can supply the generated gate signals to the plurality of gate lines GL.

The gate driving circuit GDC supplies the gate signals to the gate lines GL according to the gate driving control signals GCS supplied from the display controller DCTR. The gate driving circuit GDC can be disposed on one side or both sides of the display panel 100 in a gate in panel (GIP) method.

The gate driving circuit GDC sequentially outputs the gate signals to the plurality of gate lines GL under control of the display controller DCTR. The gate driving circuit GDC can sequentially supply the gate signals to the gate lines GL by shifting the gate signals using shift registers.

The gate signals can include a scan signal SC and an emission control signal EM in an organic light emitting display apparatus. The scan signal SC includes a scan signal pulse swinging between the first gate voltage and the second gate voltage. The emission control signal EM can include an emission control signal pulse swinging between a third gate voltage and a fourth gate voltage.

The scan signal pulse is synchronized with a data voltage Vdata to select the sub-pixels SP of a line in which data is to be written. The emission control signal EM defines an emission time of each of the sub-pixels SP.

The gate driving circuit GDC can include an emission control signal driver EDC outputting the emission control signal EM and at least one scan driver SDC outputting the scan signal SC.

The emission control signal driver EDC outputs the emission control signal EM in response to a start pulse and a shift clock from the display controller DCTR, and sequentially shifts the emission control signal pulse according to the shift clock.

The at least one scan driver SDC outputs the scan signal SC in response to the start pulse and the shift clock from the display controller DCTR, and shifts the scan signal pulse according to a shift clock timing.

In the gate driving circuit GDC disposed in the GIP method, the shift registers can be configured symmetrically on both sides of the display area DA. In addition, in the gate driving circuit GDC, the shift register on one side of the display area DA can be configured to include the at least one scan driver SDC and the emission control signal driver EDC, and the shift register on the other side of the display area DA can be configured to include the at least one scan driver SDC, respectively. However, the present disclosure is not limited thereto, and the emission control signal driver EDC and the at least one scan driver SDC can be differently disposed according to embodiments.

The data driving circuit DDC can be connected to the display panel DP in a tape automated bonding (TAB) method, can be connected to a bonding pad of the display panel DP in a chip on glass (COG) or chip on panel (COP) method, or can be implemented in a chip on film (COF) method and connected to the display panel DP.

The gate driving circuit GDC can be connected to the display panel DP in the tape automated bonding (TAB) method, can be connected to a bonding pad of the display panel DP in the chip on glass (COG) or chip on panel (COP) method, or can be connected to the display panel DP in the chip on film (COF) method. Alternatively, the gate driving circuit GDC can be formed in a gate in panel (GIP) type in the non-display area NDA of the display panel DP. The gate driving circuit GDC can be disposed on or connected to the substrate. For example, in the case of the GIP type, the gate driving circuit GDC can be disposed in the non-display area NDA of the substrate. The gate driving circuit GDC can be connected to the substrate in the case of a chip on glass (COG) type or a chip on film (COF) type.

Meanwhile, at least one driving circuit of the data driving circuit DDC and the gate driving circuit GDC can be disposed in the display area DA of the display panel DP. For example, at least one driving circuit of the data driving circuit DDC and the gate driving circuit GDC can be disposed not to overlap the sub-pixels SP, or can be disposed to overlap the sub-pixels SP in part or entirely.

The data driving circuit DDC can be connected to one side (e.g., an upper side or a lower side) of the display panel DP. Depending on a driving method, a panel design method or the like, the data driving circuit DDC can be connected to both sides (e.g., the upper and lower sides) of the display panel DP or can be connected to two or more of four side surfaces of the display panel DP.

The gate driving circuit GDC can be connected to one side (e.g., a left side or a right side) of the display panel DP. Depending on the driving method, the panel design method or the like, the gate driving circuit GDC can be connected to both sides (e.g., the left and right sides) of the display panel DP or can be connected to two or more of four side surfaces of the display panel DP.

The display controller DCTR can be implemented as a component separate from the data driving circuit DDC, or can be integrated with the data driving circuit DDC and implemented as an integrated circuit.

The display controller DCTR can be a timing controller used in general display technology, can be a control device capable of performing other control functions by including the timing controller, or a control device different from the timing controller, or can be a circuit in the control device. The display controller DCTR can be implemented with various circuits or electronic components such as an integrated circuit (IC), a field programmable gate array (FPGA), an application specific integrated circuit (ASIC), or a processor.

The display controller DCTR can be mounted on a printed circuit board or a flexible printed circuit, and can be electrically connected to the data driving circuit DDC and the gate driving circuit GDC through the printed circuit board or the flexible printed circuit.

The display controller DCTR can transmit and receive signals to and from the data driving circuit DDC according to one or more predetermined interfaces. Here, for example, the interfaces can include a low voltage differential signaling (LVDS) interface, an embedded clock point-to-point interface (EPI), a serial peripheral interface (SPI), and the like.

To further provide a touch sensing function as well as an image display function, the organic light emitting display apparatus 100 according to exemplary embodiments of the present disclosure can include a touch sensor, and a touch sensing circuit that detects whether a touch has occurred by a touch object such as a finger or a pen by sensing the touch sensor and the touch sensor, or detects a touch position.

The touch sensing circuit can further include a touch driving circuit that generates and outputs touch sensing data by driving and sensing the touch sensor, and a touch controller that can sense occurrence of the touch or detect the touch position using the touch sensing data.

The touch sensor can include a plurality of touch electrodes. The touch sensor can further include a plurality of touch lines for electrically connecting the plurality of touch electrodes and the touch driving circuit.

The touch sensor can be present in the form of a touch panel outside the display panel DP or present within the display panel DP. When the touch sensor exists outside the display panel DP in the form of a touch panel, the touch sensor is referred to as an external type. When the touch sensor is the external type, the touch panel and the display panel DP can be separately manufactured and combined during an assembly process. The external type of touch panel can include a substrate for a touch panel, a plurality of touch electrodes on the substrate for the touch panel, and the like.

When the touch sensor is present within the display panel DP, the touch sensor can be formed on the substrate SUB along with signal lines and electrodes related to display driving during a manufacturing process of the display panel DP.

The touch driving circuit TDC can supply a touch driving signal to at least one of the plurality of touch electrodes and sense the at least one of the plurality of touch electrodes to generate touch sensing data.

The touch sensing circuit can perform touch sensing using a self-capacitance sensing method or a mutual-capacitance sensing method.

When the touch sensing circuit performs touch sensing in the self-capacitance sensing method, the touch sensing circuit can perform touch sensing based on capacitance between each touch electrode and a touch object (e.g., a finger or a pen).

According to the self-capacitance sensing method, each of the plurality of touch electrodes can serve as both a driving touch electrode and a sensing touch electrode. The touch driving circuit TDC can drive an entirety or part of the plurality of touch electrodes and sense the entirety or part of the plurality of touch electrodes.

When the touch sensing circuit performs touch sensing in the mutual-capacitance sensing method, the touch sensing circuit can perform touch sensing based on capacitance between touch electrodes.

According to the mutual-capacitance sensing method, the plurality of touch electrodes are divided into driving touch electrodes and sensing touch electrodes. The touch driving circuit can drive the driving touch electrodes and sense the sensing touch electrodes.

The touch driving circuit and the touch controller included in the touch sensing circuit can be implemented as separate devices or a single device. Also, the touch driving circuit and the data driving circuit DDC can be implemented as separate devices or can be implemented as a single device.

In addition, the organic light emitting display apparatus 100 can further include a power supply circuit for supplying various types of power to the display driving circuit and/or the touch sensing circuit, and the like.

The organic light emitting display apparatus 100 according to exemplary embodiments of the present disclosure can be a mobile terminal such as a smart phone or tablet, or a monitor or television (TV) of various sizes, but the present disclosure is not limited thereto. In addition, the organic light emitting display apparatus 100 according to exemplary embodiments of the present disclosure can be a display of various sizes and various types, capable of displaying various kinds of information or images.

As described above, in the display panel DP, the display area DA can include the normal area NA and the one or more optical areas DA1 and DA2.

Hereinafter, it is assumed that the display area DA includes both the normal area NA and the first optical area DA1 and the second optical area DA2 (FIGS. 1C and 1D), for convenience of explanation.

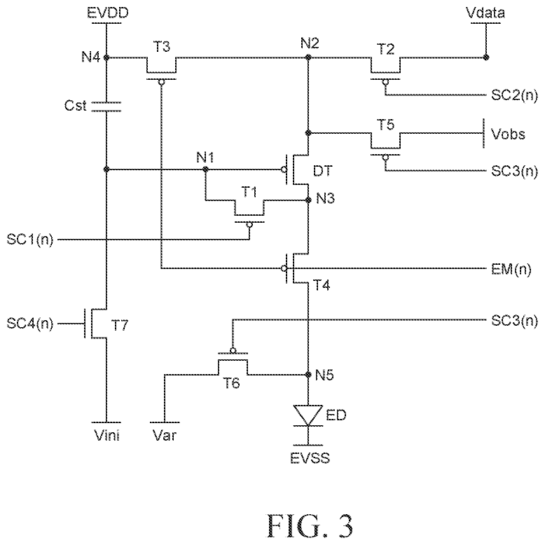

FIG. 3 is an equivalent circuit diagram of sub-pixels in a display panel according to an exemplary embodiment of the present disclosure.

Referring to FIG. 3, each of the sub-pixels SP disposed in the normal area NA, the first optical area DA1, and the second optical area DA2 that are included in the display area DA of the display panel DP, can include a light emitting element ED, a driving transistor DRT for driving the light emitting element ED, a scan transistor SCT for transferring the data voltage VDATA to a first node N1 of the driving transistor DRT, a storage capacitor Cst for maintaining a constant voltage during one frame, and the like.

The driving transistor DRT can include the first node N1 to which the data voltage can be applied, a second node N2 electrically connected to the light emitting element ED, and a third node N3 to which a driving voltage ELVDD is applied from a driving voltage line DVL. In the driving transistor DRT, the first node N1 can be a gate node, the second node N2 can be a source node or a drain node, and the third node N3 can be a drain node or a source node.

The light emitting element ED can include an anode electrode AE, a light emitting layer EL, and a cathode electrode CE. The anode electrode AE can be a pixel electrode disposed in each of the sub-pixels SP and can be electrically connected to the second node N2 of the driving transistor DRT of each sub-pixel SP. The cathode electrode CE can be a common electrode commonly disposed in the plurality of sub-pixels SP, and a ground voltage ELVSS can be applied to the cathode electrode CE. Conversely, the anode electrode AE can be a common electrode, and the cathode electrode CE can be a pixel electrode. Hereinafter, for convenience of explanation, it is assumed that the anode electrode AE is a pixel electrode and the cathode electrode CE is a common electrode.

When the light emitting element ED is an organic light emitting diode, the light emitting layer EL of the light emitting element ED can include an organic light emitting layer containing an organic material.

On/off of the scan transistor SCT can be controlled by a scan signal SCAN, which is a gate signal applied through the gate line GL, and the scan transistor SCT can be electrically connected between the first node N1 of the driving transistor DRT and the data line DL.

The storage capacitor Cst can be electrically connected between the first node N1 and the second node N2 of the driving transistor DRT.

As illustrated in FIG. 3, each sub-pixel SP can have a 2T (Transistor) 1C (Capacitor) structure including two transistors DRT and SCT and one capacitor Cst. In some cases, it can further include one or more transistors, or can further include one or more capacitors.

The storage capacitor Cst is not a parasitic capacitor (e.g., Cgs or Cgd) that is an internal capacitor that can exist between the first node N1 and the second node N2 of the driving transistor DRT, but can be an external capacitor intentionally designed outside the driving transistor DRT.

Each of the driving transistor DRT and scan transistor SCT can be an n-type transistor or a p-type transistor.

Since circuit elements (in particular, the light emitting elements ED) in each of the sub-pixels SP are vulnerable to external moisture or oxygen, an encapsulation layer ENCAP can be disposed on the display panel DP to prevent penetration of external moisture or oxygen into the circuit elements (in particular, the light emitting elements ED). The encapsulation layer ENCAP can be disposed to cover the light emitting elements ED.

Meanwhile, as one method for increasing the transmittance of at least one of the first optical area DA1 and the second optical area DA2, a pixel density differential design method can be applied.

According to the pixel density differential design method, the display panel DP can be designed such that the number of the sub-pixels per unit area in at least one of the first optical area DA1 and the second optical area DA2 is less than the number of the sub-pixels per unit area in the normal area NA.

However, in some cases, as another method for increasing the transmittance of at least one of the first optical area DA1 and the second optical area DA2, a pixel size differential design method can be applied. According to the pixel size differential design method, the display panel DP can be designed such that the number of the sub-pixels per unit area in at least one of the first optical area DA1 and the second optical area DA2 is equal to or similar to the number of the sub-pixels per unit area in the normal area NA, while a size of each of the sub-pixels SP (i.e., a size of an emission area) disposed in at least one of the first optical area DA1 and the second optical area DA2 is smaller than a size of each of the sub-pixels SP (i.e., a size of an emission area) disposed in the normal area NA.

Hereinafter, among two methods (the pixel density differential design method and the pixel size differential design method) for increasing the transmittance of at least one of the first optical area DA1 and the second optical area DA2, it is assumed that the pixel density differential design method is applied, for convenience of explanation.

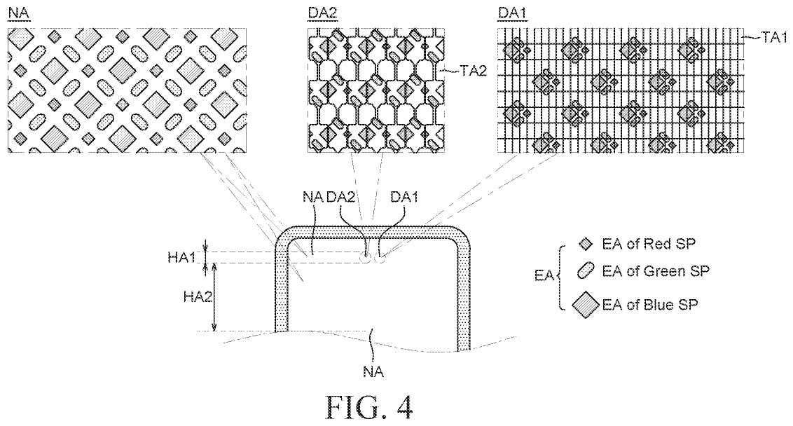

FIG. 4 is a view illustrating an example in which sub-pixels of a display area are disposed according to an exemplary embodiment of the present disclosure. Particularly, FIG. 4 illustrates arrangements of sub-pixels SP in three areas NA, DA1, and DA2 included in the display area DA as an example.

Referring to FIG. 4, the plurality of sub-pixels SP can be disposed in each of the normal area NA, the first optical area DA1 and the second optical area DA2 included in the display area DA.

For example, the plurality of sub-pixels SP can include red sub-pixels Red SP for emitting red light, green sub-pixels Green SP for emitting green light, and blue sub-pixels Blue SP for emitting blue light. As a variation, other color combinations and arrangements are possible.

Accordingly, each of the normal area NA, the first optical area DA1, and the second optical area DA2 can include the emission areas EA of the red sub-pixels Red SP, the emission areas EA of the green sub-pixels Green SP, and the emission areas EA of the blue sub-pixels Blue SP.

Referring to FIG. 4, the normal area NA may not include a light-transmissive structure and can include the emission areas EA.

The first optical area DA1 and the second optical area DA2 include a light-transmissive structure as well as including the emission areas EA. The first optical area DA1 can include the emission areas EA and first transmissive areas TA1, and the second optical area DA2 can include the emission areas EA and second transmissive areas TA2.

The emission areas EA and the transmissive areas TA1 and TA2 can be distinguished according to whether or not light is transmitted therethrough. For example, the emission areas EA can be areas in which light transmission is impossible, and the transmissive areas TA1 and TA2 can be areas in which light transmission is possible.

Also, the emission areas EA and the transmissive areas TA1 and TA2 can be distinguished according to whether or not a specific metal layer is formed therein. For example, a cathode electrode can be formed in the emission areas EA, and the cathode electrode may not be formed in the transmissive areas TA1 and TA2. In addition, a light blocking layer is formed in the emission areas EA, but the light blocking layer may not be formed in the transmissive areas TA1 and TA2.

A deposition blocking layer formed of an organic material can be disposed on the same plane as the cathode electrode in the transmissive areas TA1 and TA2. During a process of forming the cathode electrode, a cathode electrode material is not deposited on the deposition blocking layer, so the cathode electrode can be selectively formed on the substrate SUB.

Since the first optical area DA1 includes the first transmissive areas TA1 and the second optical area DA2 includes the second transmissive areas TA2, both of the first optical area DA1 and the second optical area DA2 can transmit light therethrough.

The transmittance of the first optical area DA1 and the transmittance of the second optical area DA2 can be equal to each other. In this case, the first transmissive area TA1 of the first optical area DA1 and the second transmissive area TA2 of the second optical area DA2 can have the same shape or size. Alternatively, even if shapes or sizes of the first transmissive areas TA1 of the first optical area DA1 and the second transmissive areas TA2 of the second optical area DA2 are different, a proportion of the first transmissive areas TA1 in the first optical area DA1 and a proportion of the second transmissive areas TA2 in the second optical area DA2 can be equal to each other.

Unlike this, the transmittance (the degree of transmittance) of the first optical area DA1 and the transmittance (the degree of transmittance) of the second optical area DA2 can be different from each other. In this case, the first transmissive areas TA1 of the first optical area DA1 and the second transmissive areas TA2 of the second optical area DA2 can have different shapes or sizes. Alternatively, even if shapes or sizes of the first transmissive areas TA1 of the first optical area DA1 and the second transmissive areas TA2 of the second optical area DA2 are identical to each other, the proportion of the first transmissive areas TA1 in the first optical area DA1 and the proportion of the second transmissive areas TA2 in the second optical area DA2 can be different from each other.

For example, when the optical electronic device overlapping the first optical area DA1 is a camera and the optical electronic device overlapping the second optical area DA2 is a detection sensor, the camera can require a larger amount of light than the detection sensor.

Accordingly, the transmittance of the first optical area DA1 can be higher than the transmittance of the second optical area DA2. In this case, the first transmissive areas TA1 of the first optical area DA1 can have a larger size than the second transmissive areas TA2 of the second optical area DA2. Alternatively, even if the first transmissive areas TA1 of the first optical area DA1 have a size equal to that of the second transmissive areas TA2 of the second optical area DA2, the proportion of the first transmissive areas TA1 in the first optical area DA1 can be greater than the proportion of the second transmissive areas TA2 in the second optical area DA2.

Hereinafter, for convenience of explanation, a case where the transmittance of the first optical area DA1 is greater than that of the second optical area DA2 will be described as an example.

The transmissive areas TA1 and TA2 illustrated in FIG. 4 can also be referred to as transparent areas, and the transmittance can also be referred to as transparency.

In an exemplary embodiment of the present disclosure, it is assumed that the first optical area DA1 and the second optical area DA2 are located at an upper end portion of the display area of the display panel and disposed side by side in a lateral direction, as illustrated in FIG. 4.

Referring to FIG. 4, a horizontal display area in which the first optical area DA1 and the second optical area DA2 are disposed is referred to as a first horizontal display area HA1, and a horizontal display area in which the first optical area DA1 and the second optical area DA2 are not disposed is referred to as a second horizontal display area HA2.

The first horizontal display area HA1 can include the normal area NA, the first optical area DA1 and the second optical area DA2. On the other hand, the second horizontal display area HA2 can include only the normal area NA.

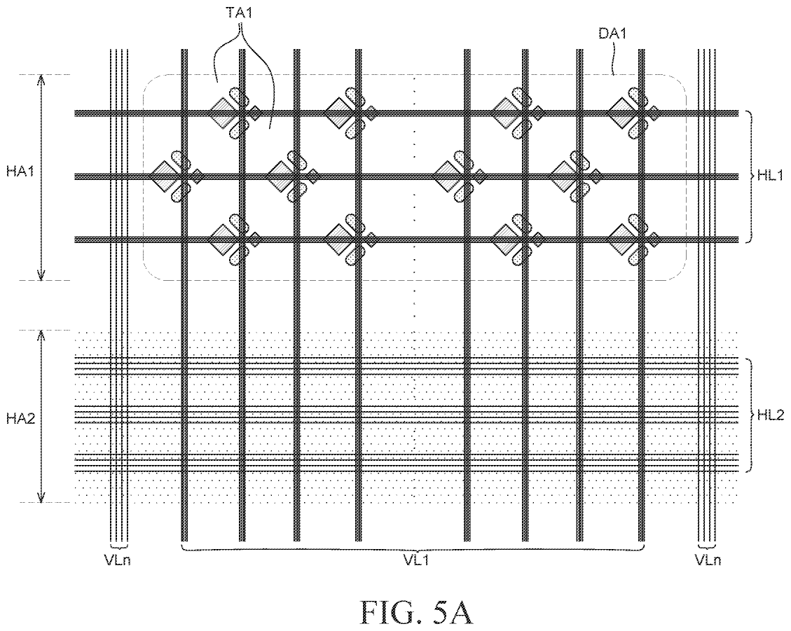

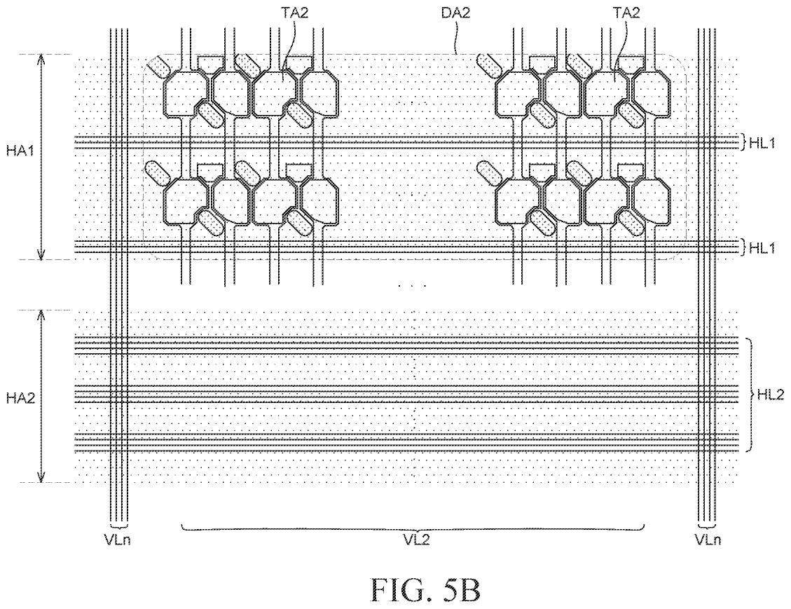

FIG. 5A is a view illustrating an example in which signal lines are disposed in each of a first optical area and a normal area in the display panel according to an exemplary embodiment of the present disclosure.

FIG. 5B is a view illustrating an example in which signal lines are disposed in each of a second optical area and a normal area in the display panel according to an exemplary embodiment of the present disclosure.

Particularly, FIG. 5A illustrates arrangements of signal lines in each of the first optical area DA1 and the normal area NA in the display panel DP according to an exemplary embodiment of the present disclosure, and FIG. 5B illustrates arrangements of signal lines in each of the second optical area DA2 and the normal area NA in the display panel DP according to an exemplary embodiment of the present disclosure.

In the example of FIG. 5A, a portion of the first horizontal display area HA1 and a portion of the first optical area DA1 are illustrated. In the example of FIG. 5B, a portion of the second horizontal display area HA2 and a portion of the second optical area DA2 are illustrated. Also, as illustrated in FIGS. 5A and 5B, the first horizontal display area HA1 includes the normal area NA, the first optical area DA1 and the second optical area DA2, and the second horizontal display area HA2 includes only the normal area NA.

Various types of horizontal lines HL1 and HL2 and vertical lines VLn, VL1 and VL2 can be disposed on the display panel DP.

In an exemplary embodiment of the present disclosure, a horizontal direction and a vertical direction mean two directions that intersect, and the horizontal direction and the vertical direction can differ depending on a viewing direction. For example, in an exemplary embodiment of the present disclosure, the horizontal direction can mean a direction in which one gate line is disposed to extend, and the vertical direction can mean a direction in which one data line is disposed to extend. Further, these horizontal and vertical directions can be referred to herein as first and second directions, or second and first directions, respectively, and can form an angle less than 90 degrees. In fact, the terms “horizontal” and “vertical” in the present disclosure can be referred to first and second, or second and first, respectively, and can cover non-perpendicular positions.

Referring to FIGS. 5A and 5B, the horizontal lines disposed on the display panel DP can include first horizontal lines HL1 disposed in the first horizontal display area HA1 and second horizontal lines HL2 disposed in the second horizontal display area HA2. In this case, the first horizontal line HL1 and the second horizontal line HL2 can be gate lines. The gate lines can include various types of gate lines according to the structure of the sub-pixel.

Referring to FIGS. 5A and 5B, the vertical lines disposed on the display panel DP can include normal vertical lines VLn disposed only in the normal area, first vertical lines VL1 passing both the first optical area DA1 and the normal area, and second vertical lines VL2 passing both the second optical area DA2 and the normal area.

The vertical lines disposed on the display panel DP can include the data lines, the driving voltage line, and the like, and can further include a reference voltage line, an initialization voltage line and the like. For example, the normal vertical lines VLn, the first vertical lines VL1, and the second vertical lines VL2 can include the data lines, the driving voltage line, and the like, and can further include the reference voltage line, the initialization voltage line, and the like.

In an exemplary embodiment of the present disclosure, the term “horizontal” of the horizontal line merely means that a signal is transmitted from a left side (or a right side) to the right side (or the left side) and may not mean that the horizontal line extends in the form of a straight line only in an accurate horizontal direction. For example, in FIGS. 5A and 5B, the first horizontal line HL1 and the second horizontal line HL2 are respectively illustrated as straight lines, but at least one of the first horizontal line HL1 and the second horizontal line HL2 can include a bent or curved portion.

In an exemplary embodiment of the present disclosure, the term “vertical” of the vertical line merely means that a signal is transmitted from an upper side (or a lower side) to the lower side (or the upper side) and may not mean that the vertical line extends in the form of a straight line only in an accurate vertical direction. For example, in FIGS. 5A and 5B, the normal vertical lines VLn, the first vertical lines VL1, and the second vertical lines VL2 are respectively illustrated as straight lines, but at least one of the normal vertical line VLn, the first vertical line VL1, and the second vertical line VL2 can include a bent or curved portion.

Referring to FIGS. 4 and 5A, the first optical area DA1 included in the first horizontal area HA1 can include the emission areas EA and the first transmissive area TA1. Within the first optical area DA1, an area outside the first transmissive area TA1 can include the emission areas EA.

Referring to FIG. 5A, to improve the transmittance of the first optical area DA1, the first horizontal lines HL1 passing through the first optical area DA1 can pass through the first optical area DA1 while avoiding the first transmissive areas TA1 within the first optical area DA1. Thus, each of the first horizontal lines HL1 passing through the first optical area DA1 can include a curved section or a bending section that detours outside an outer edge of each first transmissive area TA1. The first horizontal lines HL1 passing through the first optical area DA1 and the second horizontal lines HL2 not passing through the first optical area DA1 can have different shapes or lengths.

In addition, to improve the transmittance of the first optical area DA1, the first vertical lines VL1 passing through the first optical area DA1 can pass through the first optical area DA1 while avoiding the first transmissive areas TA1 within the first optical area DA1. Thus, each of the first vertical lines VL1 passing through the first optical area DA1 can include a curved section or a bending section that detours outside the outer edge of each first transmissive area TA1. The first vertical lines VL1 passing through the first optical area DA1 and the normal vertical lines VLn disposed in the normal area NA without passing through the first optical area DA1 can have different shapes or lengths.

Referring to FIG. 5A, the first transmissive areas TA1 included in the first optical area DA1 in the first horizontal area HA1 can be disposed in an oblique direction.

Referring to FIG. 5A, in the first optical area DA1 in the first horizontal area HA1, the emission areas can be disposed between two first transmissive areas TA1 adjacent to each other. In the first optical area DA1 in the first horizontal area HA1, the emission areas can be disposed between two first transmissive areas that are vertically adjacent to each other.

Referring to FIGS. 4 and 5B, the second optical area DA2 included in the first horizontal area HA1 can include the emission areas EA and the second transmissive areas TA2. Within the second optical area DA2, an area outside the second transmissive area TA2 can include the emission areas EA.

As illustrated in FIG. 5B, positions and arrangements of the emission areas EA and the second transmissive areas TA2 in the second optical area DA2 can be different from positions and arrangements of the emission areas EA and the first transmissive areas TA1 in the first optical area DA1 in FIG. 5A. However, the positions and arrangements of the emission areas EA and the second transmissive areas TA2 in the second optical area DA2 can be identical to the positions and arrangements of the emission areas EA and the first transmissive areas TA1 in the first optical area DA1 in FIG. 5A.

Referring to FIG. 5B, within the second optical area DA2, the second transmissive areas TA2 can be disposed in the horizontal direction (a lateral direction), and the emission areas EA may not be disposed between the two second transmissive areas TA2 adjacent in the horizontal direction (the lateral direction). Also, within the second optical area DA2, the second transmissive areas TA2 can be disposed in a longitudinal direction (the vertical direction), and the emission areas EA can be disposed between the second transmissive areas TA2 adjacent in the longitudinal direction (the vertical direction). For example, the emission areas EA can be disposed between two rows of the second transmissive areas TA2.

The positions and arrangements of the emission areas EA and the second transmissive areas TA2 in the second optical area DA2 in FIG. 5B are different from the positions and arrangements of the emission areas EA and the first transmissive areas TA1 in the first optical area DA1 in FIG. 5A. Therefore, as illustrated in FIG. 5B, when the first horizontal lines HL1 pass through the second optical area DA2 in the first horizontal area HA1 and the normal area around the second optical area DA2, the first horizontal lines HL1 can pass the areas in a form different from that in FIG. 5A. However, when the first horizontal lines HL1 pass through the second optical area DA2 in the first horizontal area HA1 and the normal area around the second optical area DA2, the first horizontal lines HL1 can pass the areas in the same form as that in FIG. 5A.

Referring to FIG. 5B, when the first horizontal line HL1 passes through the second optical area DA2 in the first horizontal area HA1 and the normal area NA around the second optical area DA2, the first horizontal line HL1 can pass linearly between the second transmissive areas TA2 vertically adjacent, without having a curved section or a bending section.

For example, one first horizontal line HL1 can have a curved section or bending section in the first optical area DA1, but may not have a curved section or bending section in the second optical area DA2.

In addition, to improve the transmittance of the second optical area DA2, the second vertical lines VL2 passing through the second optical area DA2 can pass through the second optical area DA2 while avoiding the second transmissive areas TA2 within the second optical area DA2. As illustrated in FIG. 5B, each of the second vertical lines VL2 passing through the second optical area DA2 can include a curved section or a bending section that detours outside an outer edge of each second transmissive area TA2. Accordingly, the second vertical lines VL2 passing through the second optical area DA2 and the normal vertical lines VLn disposed in the normal area without passing through the second optical area DA2 can have different shapes or lengths.

When the first horizontal lines HL1 passing through the first optical area DA1 have curved sections or bending sections that detour outside the outer edges of the first transmissive areas TA1, the first horizontal lines HL1 passing through the first optical area DA1 and the second optical area DA2 can be longer than the second horizontal lines HL2 disposed only in the normal area NA.

Accordingly, the resistance of the first horizontal lines HL1 passing through the first optical area DA1 and the second optical area DA2 (hereinafter referred to as ‘first resistance’) can be greater than the resistance of the second horizontal lines HL2 disposed only in the normal area NA (hereinafter referred to as ‘second resistance’).

The first optical area DA1 overlapping the first optical electronic device 170a at least in part includes a plurality of the first transmissive areas TA1 and the second optical area DA2 overlapping the second optical electronic device 170b at least in part includes a plurality of the second transmissive areas TA2. Thus, the number of the sub-pixels to which the first horizontal lines HL1 passing through the first optical area DA1 and the second optical area DA2 are connected can be different from the number of the sub-pixels to which the second horizontal lines HL2 disposed only in the normal area NA without passing through the first optical area DA1 and the second optical area DA2 are connected.

For example, the first optical area DA1 and the second optical area DA2 can have fewer sub-pixels per unit area than the normal area NA.

The number (first number) of the sub-pixels to which the first horizontal lines HL1 passing through the first optical area DA1 and the second optical area DA2 are connected can be less than the number (second number) of the sub-pixels to which the second horizontal lines HL2 disposed only in the normal area NA are connected.

A difference between the first number and the second number can vary according to a difference between resolution of each of the first optical area DA1 and the second optical area DA2 and resolution of the normal area NA. For example, as the difference between the resolution of each of the first optical area DA1 and the second optical area DA2 and the resolution of the normal area NA increases, the difference between the first number and the second number can increase.

As described above, since the first number of the sub-pixels to which the first horizontal lines HL1 passing through the first optical area DA1 and the second optical area DA2 are connected is less than the second number of the sub-pixels to which the second horizontal lines HL2 disposed only in the normal area NA are connected, an area where the first horizontal lines HL1 overlap surrounding other electrodes or lines can be smaller than an area where the second horizontal lines HL2 overlap surrounding other electrodes or lines.

Therefore, a parasitic capacitance formed between the first horizontal line HL1 and surrounding other electrodes or lines (hereinafter referred to as ‘first capacitance’) can be significantly less than a parasitic capacitance formed between the second horizontal line HL2 and surrounding other electrodes or lines (hereinafter referred to as ‘second capacitance’).

Considering a magnitude relationship between the first resistance and the second resistance (first resistance ≥second resistance) and a magnitude relationship between the first capacitance and the second capacitance (first capacitance <<second capacitance), a resistance-capacitance (RC) value (hereinafter, referred to as ‘a first RC value’) of the first horizontal line HL1 passing through the first optical area DA1 and the second optical area DA2 can be much smaller than an RC value (hereinafter referred to as ‘second RC value’) of the second horizontal line HL2 disposed only in the normal area NA without passing through the first optical area DA1 and the second optical area DA2 (i.e., first RC value <<second RC value).

Due to a difference between the first RC value of the first horizontal line HL1 and the second RC value of the second horizontal line HL2 (hereinafter, referred to as ‘RC load difference’), signal transmission characteristics through the first horizontal line HL1 can be different from signal transmission characteristics through the second horizontal line HL2.

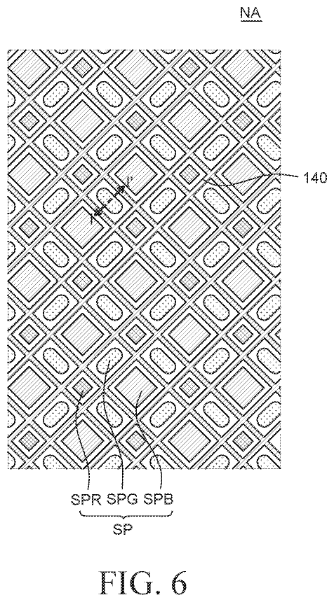

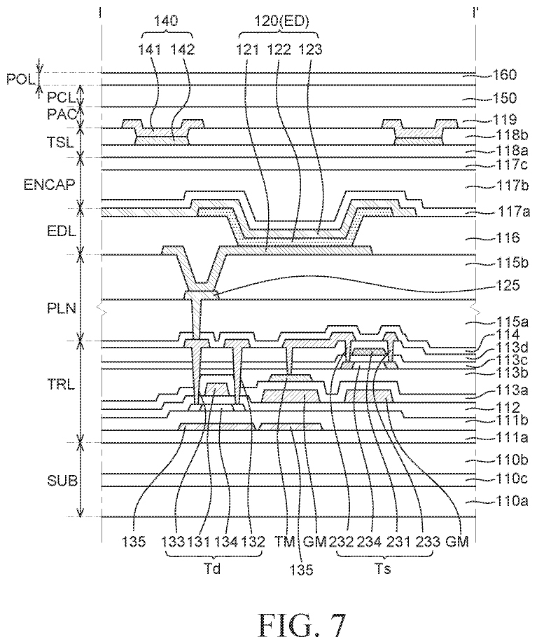

Hereinafter, a cross-sectional structure of the normal area NA of the organic light emitting display apparatus 100 according to an exemplary embodiment of the present disclosure will be described in detail with reference to FIGS. 6 and 7.

FIG. 6 is a schematic enlarged plan view illustrating a normal area of the display panel according to an exemplary embodiment of the present disclosure. FIG. 7 is a cross-sectional view taken along line I-I′ of FIG. 6.

In FIG. 6, for convenience of explanation, only the plurality of sub-pixels SP and a plurality of touch electrodes 140 disposed in the normal area NA are illustrated.

The sub-pixels SP are minimum units that constitute a screen and can include a plurality of light emitting elements (ED) 120 to correspond to the plurality of sub-pixels SP, respectively. For example, the plurality of light emitting elements 120 can be disposed to correspond to the plurality of sub-pixels SP, respectively, and accordingly, the plurality of sub-pixels SP can be expressed as the plurality of light emitting elements 120.

Each of the plurality of sub-pixels SP can emit light of different wavelengths. For example, the plurality of sub-pixels SP can include a red sub-pixel SPR, a green sub-pixel SPG, and a blue sub-pixel SPB. However, the present disclosure is not limited thereto, and the plurality of sub-pixels SP can further include a white sub-pixel.

The touch electrodes 140 respectively having mesh patterns in which they interest each other can be disposed between the plurality of sub-pixels SP in the normal area NA. Accordingly, a user's touch input can be detected on an upper surface of the plurality of sub-pixels SP disposed in the normal area.

Referring to FIG. 7, a transistor layer TRL can be disposed on the substrate SUB, and a planarization layer PLN can be disposed on the transistor layer TRL. In addition, a light emitting element layer EDL can be disposed on the planarization layer PLN, the encapsulation layer ENCAP can be disposed on the light emitting element layer EDL, a touch sensing layer TSL can be disposed on the encapsulation layer ENCAP, and a protective layer PAC can be disposed on the touch sensing layer TSL. In addition, an organic material layer PCL can be disposed on the protective layer PAC, and a polarization layer POL can be disposed on the organic material layer PCL.

In FIG. 7, a green sub-pixel SPG among the plurality of sub-pixels SP disposed in the normal area NA is illustrated as an example, but the sub-pixels SP emitting light of other colors can also have the same overall structure as that of the green sub-pixel SPG, with only a difference in light output by a light emitting stack that constitutes the light emitting element 120.

The substrate SUB is a component for supporting various components included in the organic light emitting display apparatus 100 and can be formed of an insulating material. The substrate SUB can include a first substrate 110a, a second substrate 110b, and an interlayer insulating layer 110c. For example, the first substrate 110a and the second substrate 110b can be polyimide (PI) substrates. The interlayer insulating layer 110c can be disposed between the first substrate 110a and the second substrate 110b. In this manner, since the substrate SUB is configured to include the first substrate 110a, the second substrate 110b, and the interlayer insulating layer 110c, moisture permeation can be prevented. For example, the first substrate 110a and the second substrate 110b can be polyimide (PI) substrates.

In the normal area NA, various patterns 131, 132, 133, 134, 231, 232, 233, and 234 to form transistors such as a driving transistor Td and at least one switching transistor Ts and at least one capacitor, various insulating layers 111a, 111b, 112, 113a, 113b, and 114, and various metal patterns TM, GM, and 135 can be disposed in the transistor layer TRL.

Hereinafter, a stacked structure of the transistor layer TRL will be described in more detail.

A multi-buffer layer 111a can be disposed on the second substrate 110b, and an active buffer layer 111b can be disposed on the multi-buffer layer 111a.

A metal layer 135 can be disposed on the multi-buffer layer 111a. Here, the metal layer 135 can function as a light shield and can also be referred to as a light blocking layer. The active buffer layer 111b can be disposed on the metal layer 135.

A first active layer 134 of the driving transistor Td can be disposed on the active buffer layer 111b. For example, the first active layer 134 can be formed of poly-polycrystalline silicon (p-Si), amorphous silicon (a-Si), or an oxide semiconductor, but is not limited thereto. Meanwhile, the driving transistor Td is formed on the active buffer layer 111b and includes the first active layer 134, a first gate insulating layer 112 covering the first active layer 134, a first gate electrode 131 disposed on the first gate insulating layer 112, a first interlayer insulating layer 113a covering the first gate electrode 131, a second gate insulating layer 113b disposed on the first interlayer insulating layer 113a, a third interlayer insulating layer 113c disposed on the second gate insulating layer 113b, and a first source electrode 132 and a first drain electrode 133 disposed on the third interlayer insulating layer 113c.

The first gate insulating layer 112 can be disposed on the first active layer 134. The first gate insulating layer 112 can be formed of silicon oxide (SiOx), silicon nitride (SiNx), or a multiple layer thereof.

In addition, the first gate electrode 131 of the driving transistor Td can be disposed on the first gate insulating layer 112. The first gate electrode 131 is disposed to overlap the first active layer 134 on the first gate insulating layer 112. The first gate electrode 131 can be formed of various conductive materials, such as magnesium (Mg), aluminum (Al), nickel (Ni), chromium (Cr), molybdenum (Mo), tungsten (W), gold (Au), or alloys thereof, but the present disclosure is not limited thereto.

A gate material layer GM can be disposed on the first gate insulating layer 112 at a location different from a location where the driving transistor Td is formed.

The first interlayer insulating layer 113a can be disposed on the first gate electrode 131 and the gate material layer GM. A metal pattern TM can be disposed on the first interlayer insulating layer 113a. A second interlayer insulating layer 113b can be disposed to cover the metal pattern TM disposed on the first interlayer insulating layer 113a.

The second interlayer insulating layer 113b separates a second active layer 234 from the first active layer 134 and provides a base for forming the second active layer 234.

The second active layer 234 of the switching transistor Ts can be disposed on the second interlayer insulating layer 113b. For example, the second active layer 234 can be formed of polycrystalline silicon, amorphous silicon, or an oxide semiconductor, but is not limited thereto.

A second gate insulating layer 113c can be disposed on the second active layer 234. Additionally, a second gate electrode 231 of the switching transistor Ts can be disposed on the second gate insulating layer 113c. The second gate electrode 231 is disposed to overlap the second active layer 234 on the second gate film 113c.

The second gate insulating layer 113c covers the second active layer 234 of the switching transistor Ts. Since the second gate insulating layer 113c is formed on the second active layer 234, it is implemented as an inorganic layer. For example, the second gate insulating layer 113c can be formed of silicon oxide (SiO₂), silicon nitride (SiNx), or a multiple layer thereof.

The second gate electrode 231 is formed of a metal material. For example, the second gate electrode 231 can be a single layer or a multilayer formed of any one of molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

Meanwhile, the switching transistor Ts is formed on the second interlayer insulating layer 113b and includes the second active layer 234, the second gate insulating layer 113c covering the second active layer 234, the second gate electrode 231 disposed on the second gate insulating layer 113c, the third interlayer insulating layer 113c covering the second gate electrode 231, and a second source electrode 232 and a second drain electrode 233 disposed on the third interlayer insulating layer 113c.

The switching transistor Ts further includes a gate material layer GM that is located below the first interlayer insulating layer 113a and overlaps the second active layer 234. The gate material layer GM can secure reliability of the switching transistor Ts by blocking light incident on the second active layer 234. The gate material layer GM is formed of the same material as the first gate electrode 131 and can be formed on an upper surface of the first gate insulating layer 112. The gate material layer GM can be electrically connected to the second gate electrode 234 to form a dual gate. The first source electrode 132 and the first drain electrode 133 of the driving transistor Td and the second source electrode 232 and the second drain electrode 233 of the switching transistor Ts can be disposed on a third interlayer insulating layer 113d.

The second source electrode 232 and the second drain electrode 233, together with the first source electrode 132 and the first drain electrode 133, are simultaneously formed on the third interlayer insulating layer 113d and are formed of the same material, so that the number of mask processes can be reduced.

The first source electrode 132 and the first drain electrode 133 can be connected to one side and the other side of the first active layer 134, respectively, through contact holes provided in the third interlayer insulating layer 113d, the second gate insulating layer 113c, the second interlayer insulating layer 113b, the first interlayer insulating layer 113a, and the first gate insulating layer 112.

The second source electrode 232 and the second drain electrode 233 can be connected to one side and the other side of the second active layer 234, respectively, through contact holes provided in the third interlayer insulating layer 113d and the second gate insulating layer 113c.

The first source electrode 132 and the first drain electrode 133, and the second source electrode 232 and the second drain electrode 233 can be formed of a single layer of multiple layers of various conductive materials, such as magnesium (Mg), aluminum (Al), nickel (Ni), chromium (Cr), molybdenum (Mo), tungsten (W), gold (Au) or an alloy thereof, but the present disclosure is not limited thereto.

A portion of the first active layer 134 overlapping the first gate electrode 131 is a channel region. One of the first source electrode 132 and the first drain electrode 133 is connected to one side of the channel region in the first active layer 134 and the other thereof is connected to the other side of the channel region in the first active layer 134.

The second active layer 234 can be configured in the same form as the first active layer 134, and when the second active layer 234 is implemented with an oxide semiconductor material, it includes an intrinsic second channel which is not doped with impurities, and a second source region and a second drain region which are doped with impurities and thus, are conductive.

A passivation layer 114 can be disposed on the first source electrode 132, the first drain electrode 133, the second source electrode 232, and the second drain electrode 233. The passivation layer 114 is to protect the driving transistor Td and can be formed of an inorganic layer, for example, silicon oxide (SiOx), silicon nitride (SiNx), or a multiple layer thereof.

Meanwhile, the gate material layer GM and the metal pattern TM are disposed to overlap on the first gate insulating layer 112, so that the capacitor Cst can be implemented. The metal pattern TM can be a single layer or a multilayer formed of any one of for example, molybdenum (Mo), aluminum (Al), chromium (Cr), gold (Au), titanium (Ti), nickel (Ni), neodymium (Nd), and copper (Cu), or an alloy thereof.

The capacitor Cst stores a data voltage applied through the data line DL for a certain period of time and then provides it to the light emitting element 120. The capacitor Cst includes two electrodes corresponding to each other and a dielectric disposed between them. The first interlayer insulating layer 113a is located between the gate material layer GM and the metal pattern TM.

The gate material layer GM or the metal pattern TM in the capacitor Cst can be electrically connected to the second source electrode 232 or the second drain electrode 233 of the switching transistor Ts. However, the present disclosure is not limited thereto, and a connection relationship of the capacitor Cst can be changed depending on a pixel driving circuit.

Additionally, the metal layer 135 can be disposed on the multi-buffer layer 111a to further overlap the gate material layer GM and the metal pattern TM, so that a double capacitor Cst can be configured.

In an exemplary embodiment of the present disclosure, at least one switching transistor Ts uses an oxide semiconductor as an active layer. A transistor using an oxide semiconductor as an active layer has an excellent leakage current blocking effect and a manufacturing cost thereof is relatively inexpensive compared to a transistor using polycrystalline silicon as an active layer. Therefore, in order to reduce power consumption and lower manufacturing costs, a pixel circuit according to an exemplary embodiment of the present disclosure includes a driving transistor or at least one switching transistor using an oxide semiconductor material.

All of transistors constituting the pixel circuit, including the driving transistor, can be implemented using an oxide semiconductor as an active layer, or only some of the transistors can be implemented using an oxide semiconductor. However, it is difficult to ensure reliability of the transistors using oxide semiconductors, and transistors using polycrystalline silicon have a fast operation speed and excellent reliability. Thus, an exemplary embodiment of the present disclosure includes both transistors using oxide semiconductors and transistors using polycrystalline silicon. However, the present disclosure is not limited thereto, and depending on a design, the pixel circuit can be configured by applying only the transistors using oxide semiconductors or only the transistors using polycrystalline silicon.

The planarization layer PLN can be located on the transistor layer TRL. The planarization layer PLN can include a first planarization layer 115a and a second planarization layer 115b. The planarization layer PLN protects the driving transistor Td and planarizes an upper portion thereof.

The first planarization layer 115a can be disposed on the passivation layer 114.

A connection electrode 125 can be disposed on the first planarization layer 115a. The connection electrode 125 can be connected to one of the first source electrode 132 and the first drain electrode 133 through a contact hole provided in the first planarization layer 115a.

The second planarization layer 115b can be disposed on the connection electrode 125. The light emitting element layer EDL can be located on the second planarization layer 115b.

Hereinafter, a stacked structure of the light emitting element layer EDL will be described in detail.

An anode 121 of the light emitting element 120 can be disposed on the second planarization layer 115b. In this case, the anode 121 can be electrically connected to the connection electrode 125 through a contact hole provided in the second planarization layer 115b. The anode 121 can be formed of a metal material.

When the organic light emitting display apparatus 100 is a top emission type in which light emitted from the light emitting element 120 is emitted upwardly of the substrate SUB on which the light emitting element 120 is disposed, the anode 121 can further include a transparent conductive layer and a reflective layer on the transparent conductive layer. The transparent conductive layer can be formed of, for example, a transparent conductive oxide such as ITO or IZO, and the reflective layer can be formed of, for example, silver (Ag), aluminum (Al), gold (Au), molybdenum (Mo), tungsten. (W), chromium (Cr), or alloys thereof.

A bank 116 can be disposed to cover the anode 121. A portion of the bank 116 corresponding to the emission area of the sub-pixel can be opened. The portion of the anode 121 can be exposed to an open area where the bank 116 is opened. The bank 116 can be formed of an inorganic insulating material, such as silicon nitride (SiNx) or silicon oxide (SiOx) or an organic insulating material, such as benzocyclobutene-based resin, acrylic-based resin, or imide-based resin, but the present disclosure is not limited thereto.

An additional spacer can be located on the bank 116. The spacer can be formed of the same material as the bank 116.

A light emitting layer 122 of the light emitting element 120 can be disposed in the open area of the bank 116 and a peripheral portion thereof. Accordingly, the light emitting layer 122 can be disposed on the anode 121 exposed through the open area of the bank 116.

In exemplary embodiments of the present disclosure, the light emitting layer 122 can be an organic light emitting layer, and in addition to a light emitting layer that emits light of a specific color, it can further include at least one functional layer among a hole transport layer, a hole injection layer, an electron transport layer, and an electron injection layer. A structure in which the light emitting layer and the functional layer are stacked in this manner is referred to as a light emitting stack.

In exemplary embodiments of the present disclosure, a plurality of sub-pixels SPR, SPG, and SPB that emit light of different colors and each have a single light emitting stack are disposed in the normal area NA of the organic light emitting display apparatus 100.

A cathode 123 can be disposed on the light emitting layer 122.

The light emitting element (ED) 120 can be formed by the anode 121, the light emitting layer 122, and the cathode 123. The light emitting layer 122 can include multiple organic layers.

The encapsulation layer ENCAP can be located on the light emitting element layer EDL described above.

The encapsulation layer ENCAP can have a single layer structure or a multilayer structure. For example, the encapsulation layer ENCAP can include a first encapsulation layer 117a, a second encapsulation layer 117b, and a third encapsulation layer 117c.

In this case, the first encapsulation layer 117a and the third encapsulation layer 117c can be formed of an inorganic film, and the second encapsulation layer 117b can be formed of an organic film. Among the first encapsulation layer 117a, the second encapsulation layer 117b, and the third encapsulation layer 117c, the second encapsulation layer 117b is thickest and can serve as a planarization layer.

The first encapsulation layer 117a can be disposed on the cathode 123 and can be disposed closest to the light emitting element 120. The first encapsulation layer 117a can be formed of an inorganic insulating material capable of low-temperature deposition. For example, the first encapsulation layer 117a can be formed of silicon nitride (SiNx), silicon oxide (SiOx), silicon oxynitride (SiON), or aluminum oxide (Al₂O₃). Since the first encapsulation layer 117a is deposited in a low-temperature atmosphere, it is possible to prevent damage to the light emitting layer 122 including an organic material vulnerable to a high-temperature atmosphere during a deposition process.

The second encapsulation layer 117b can have an area smaller than the first encapsulation layer 117a. In this case, the second encapsulation layer 117b can be formed to expose both ends of the first encapsulation layer 117a. The second encapsulation layer 117b can serve as a buffer to alleviate stress between the respective layers due to bending of the flexible organic light emitting display apparatus and serve to enhance planarization performance.

For example, the second encapsulation layer 117b can be formed of an organic insulating material, such as acrylic resin, epoxy resin, polyimide, polyethylene, or silicon oxycarbon (SiOC). For example, the second encapsulation layer 117b can be formed through an inkjet method, but the present disclosure is not limited thereto.

A color filter can be disposed on the encapsulation layer ENCAP.

In addition, a structure that blocks a flow of the second encapsulation layer 117b constituting the encapsulation layer ENCAP can be disposed in the non-display area NDA. One or more structures described above can be placed at or near an end point of an inclined surface of the encapsulation layer ENCAP to prevent the encapsulation layer ENCAP from collapsing. One or more structures can be placed at or near a boundary point between the display area DA and the non-display area NDA. The structure can be composed of at least one layer formed of an organic material, and can include, for example, a lower layer formed of the same material on the same layer as the second planarization layer 115b and an upper layer formed of the same material on the same layer as the bank 116. However, the present disclosure is not limited to thereto.

The third encapsulation layer 117c can be formed to cover an upper surface and side surfaces of each of the second encapsulation layer 117b and the first encapsulation layer 117a above the substrate SUB above which the second encapsulation layer 117b is formed. In this case, the third encapsulation layer 117c can minimize or block penetration of external moisture or oxygen into the first encapsulation layer 117a and the second encapsulation layer 117b. For example, the third encapsulation layer 117c can be formed of an inorganic insulating material, such as silicon nitride (SiNx), silicon oxide (SiOx), silicon oxynitride (SiON), or aluminum oxide (Al₂O₃).

The touch sensing layer TSL can be disposed on the encapsulation layer ENCAP described above.

A touch buffer layer 118a can be disposed on the encapsulation layer ENCAP, and the touch electrode 140 can be disposed on the touch buffer layer 118a.

The touch electrode 140 can include a touch sensor electrode 141 and a bridge electrode 142 that are located on different layers. A touch interlayer insulating layer 118b can be disposed between the touch sensor electrode 141 and the bridge electrode 142.

For example, the touch sensor electrode 141 can include a first touch sensor electrode, a second touch sensor electrode, and a third touch sensor electrode that are disposed adjacent to one another. For example, the first touch sensor electrode and the second touch sensor electrode can be disposed in a first direction, but the third touch sensor electrode can be disposed in a second direction crossing the first touch sensor electrode and the second touch sensor electrode. The first touch sensor electrode and the second touch sensor electrode are electrically connected to each other. However, when the third touch sensor electrode disposed in the second direction crossing the first direction is present between the first touch sensor electrode and the second touch sensor electrode disposed in the first direction, the first touch sensor electrode and the second touch sensor electrode can be electrically connected through the bridge electrode 142 disposed on a different layer therefrom. The bridge electrode 142 can be insulated from the third touch sensor electrode by the touch interlayer insulating layer 118b.

In other words, in order to prevent the plurality of touch electrodes disposed in the first direction and the second direction from short-circuiting in areas where they intersect, the plurality of touch electrodes extending in the first direction can be electrically connected through the bridge electrodes 142.

When the touch sensing layer TSL is formed, a chemical solution (a developer or etching solution) used in a process or moisture from the outside can be generated. Therefore, by disposing the touch buffer layer 118a and then disposing the touch sensing layer TSL thereon, it is possible to prevent penetration of the chemical solution or moisture into the light emitting layer 122 including an organic material during manufacturing of the touch sensing layer TSL. Accordingly, the touch buffer layer 118a can prevent damage to the light emitting layer 122, which is vulnerable to the chemical solution or moisture.

The touch buffer layer 118a can be formed of an organic insulating material capable of being formed at a low temperature of a certain temperature (e.g., 100° C.) or less and having a low dielectric permittivity of 1 to 3 in order to prevent damage to the light emitting layer 122 including an organic material which is vulnerable to high temperature. For example, the touch buffer layer 118a can be formed of an acryl-based material, an epoxy-based material, or a siloxane-based material. As a flexible display apparatus is bent, the encapsulation layer ENCAP can be damaged, and the touch sensor electrode 141 located on an upper portion of the touch buffer layer 118a can be broken. Even if the flexible display apparatus is bent, the touch buffer layer 118a which is formed of an organic insulating material and has a planarization performance, can prevent damage to the encapsulation layer ENCAP and breakage of the touch sensor electrodes 141 and the bridge electrodes 142 constituting the plurality of touch electrodes 140.

A protective layer (PAC) 119 can be disposed to cover the plurality of touch electrodes 140, the touch routing line TL, and the ground lines GND and GRD. The protective layer 119 can be composed of an organic insulating layer.

An organic material layer (PCL) 150 is disposed to cover the protective layer 119.

If only the protective layer 119 formed of an organic insulating layer is disposed on a top layer of the organic light emitting display apparatus 100, a step caused by the touch sensing layer TSL disposed below the protective layer 119 cannot be completely compensated, causing defects in which spots caused by the plurality of touch electrodes 140 are visible to a user. Accordingly, by adding the organic material layer 150 formed of an organic insulating layer on the protective layer 119, the step at the top layer of the organic light emitting display apparatus 100 can be prevented and visibility can be improved.

The organic material layer 150 can be formed of the same material as the second encapsulation layer 117b of the encapsulation layer ENCAP, for example, can be formed of an organic insulating material such as acrylic resin, epoxy resin, polyimide, polyethylene, or silicon oxycarbon (SiOC). The organic material layer 150 can be formed using an inkjet method, but is not limited thereto.

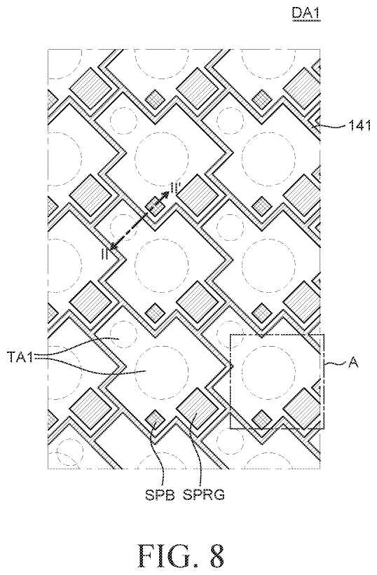

Referring to FIGS. 8 to 11, the optical area of the organic light emitting display apparatus 100 according to an exemplary embodiment of the present disclosure will be described in detail.

Hereinafter, for convenience of explanation, a case in which the display area DA includes the normal area NA and the first optical area DA1 in the display panel DP of the organic light emitting display apparatus 100 (i.e., FIGS. 1A and 1B) will be described as an example, but descriptions of the first optical area DA1 can be equally applied to the second optical area DA2.

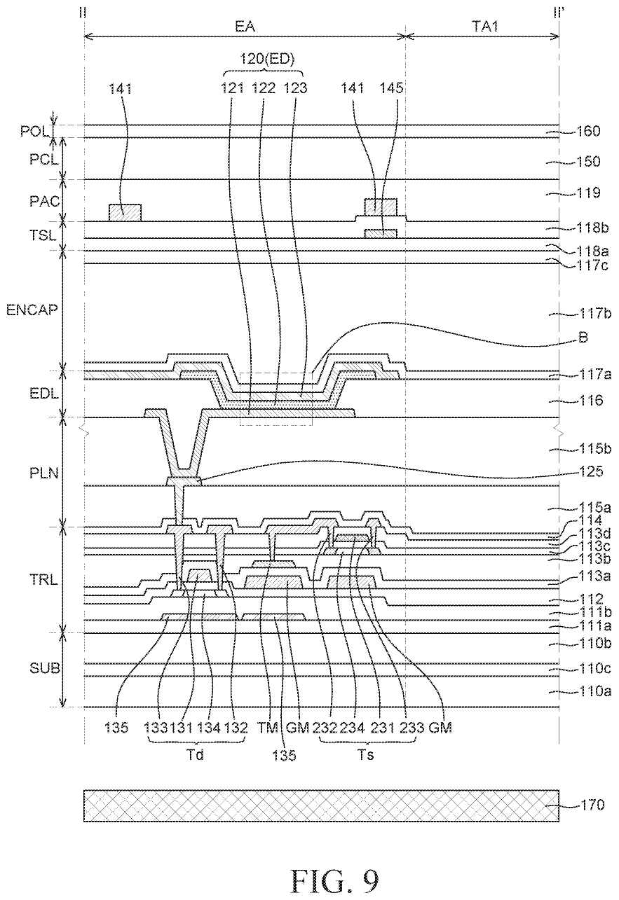

FIG. 8 is a schematic enlarged plan view illustrating the first optical area of the display panel according to an exemplary embodiment of the present disclosure. FIG. 9 is a cross-sectional view taken along line II-II′ of FIG. 8.

Referring to FIG. 8, the first optical area DA1 includes the emission areas EA in which the sub-pixels SP are disposed, and transmissive areas TA1 in which light transmission is possible since the cathodes of the sub-pixels SP are not disposed.

Compared to the normal area NA previously described with reference to FIG. 6, the first optical area DA1 not only includes the transmissive areas TA1 but also includes a smaller number of the sub-pixels per unit area.

In addition, in FIGS. 4 and 5A, it is illustrated that a red sub-pixel Red SP emitting red light, a green sub-pixel Green SP emitting green light, and a blue sub-pixel Blue SP emitting blue light per unit area are all disposed in the emission area EA of the first optical area DA1, as an example. According to another example of the display panel DP according to an exemplary embodiment of the present disclosure, as shown in FIG. 8, a plurality of sub-pixels having a structure in which a plurality of light emitting stacks that emit light of different colors per unit areas are stacked can be disposed in the first optical area DA1.

Referring to FIG. 8, in the first optical area DA1, a first sub-pixel SPRG having a structure in which a light emitting stack that emits red light and a light emitting stack that emits green light are stacked, and a second sub-pixel SPB having a structure in which a single light emitting stack that emits blue light is stacked can be disposed. Through this, in the display panel DP according to an exemplary embodiment of the present disclosure, the number of sub-pixels included per unit area of the first optical area DA1 is less than the number of sub-pixels disposed per unit area of the normal area NA, and the number of sub-pixels in a case including only the sub-pixels having a structure in which a single light emitting stack is stacked per unit area of the first optical area DA1. Accordingly, the display panel DP according to an exemplary embodiment of the present disclosure can further expand a transmissive surface area of the transmissive areas TA1 included in the first optical area DA1.

FIG. 9 shows a cross-section of the emission area where the second sub-pixel SPB of the first optical area DA1 shown in FIG. 8 is disposed and the transmissive area TA1 adjacent thereto.

Referring to FIG. 9, the emission area EA and the transmissive area TA1 of the first optical area DA1 can each basically include the substrate SUB, the transistor layer TRL, the planarization layer PLN, the light emitting element layer EDL, the encapsulation layer ENCAP, a touch sensing layer TSL, the protective layer PAC and the like.

The substrate SUB, the transistor layer TRL, the planarization layer PLN, the light emitting element layer EDL, the encapsulation layer ENCAP, the touch sensing layer TSL, and the protective layer PAC that are included in the first optical area DA1 are substantially the same as components having the same reference numerals disposed in the normal area NA of the display panel DP previously described with reference to FIG. 7, so duplicate descriptions thereof will be omitted. In addition, since the emission area where the first sub-pixel SPB is disposed in the first optical area DA1 is substantially the same as the structure of the normal area NA of the display panel DP, duplicate descriptions thereof will be omitted. Additionally, the optical electronic device 170 can be disposed below the substrate SUB in the first optical area DA1.

Hereinafter, the transmissive area TA1 disposed in the first optical area DA1 will be described.

The substrate SUB and various insulating layers 111a, 111b, 112, 113a, 113b, 114, 115a, 115b, 117a, 117b, 117c, and PAC disposed in the emission area EA of the first optical area DA1 can be equally disposed in the transmissive area TA of the first optical area DA1.

However, since the transmissive area TA1 in the first optical area DA1 overlaps with the optical electronic device 170, a transmittance of the transmissive area TA1 that allows a normal operation of the optical electronic device 170 should be secured. Accordingly, in the transmissive area TA1 of the first optical area DA1, a material layer having electrical properties or opaque properties other than the insulating material disposed in the emission area where the second sub-pixel SPB is disposed may not be disposed.

For example, metal material layers 135, 131, GM, TM, 132, 133, and 125 and the semiconductor layer 134 related to the transistors are not disposed in the transmissive area TA1. The anode 121 included in the light emitting element (ED) 120 may not be not disposed in the transmissive area TA1, the cathode 123 may not be disposed in the transmissive area TA1 except for a partial area thereof close to the emission area, and the light emitting layer 122 can or may not be disposed in the transmissive area TA1. The touch sensor electrode 141 and the bridge electrode 142 included in the touch sensor are not disposed in the transmissive area TA1.

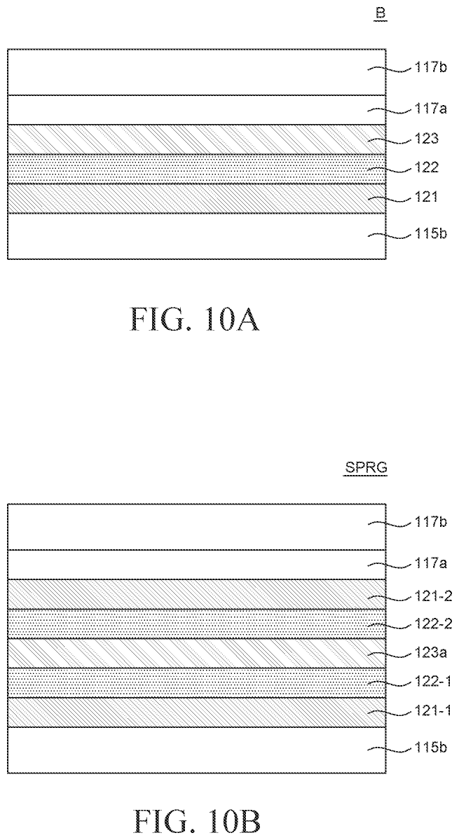

FIG. 10A is a schematic enlarged cross-sectional view of an example of a structure of the sub-pixel SPB shown in area B of FIG. 9. FIG. 10B is a schematic enlarged cross-sectional view of an example of a structure of the sub-pixel SPRG of FIG. 8.

As described in FIG. 8, in the first optical area DA1 of the display panel DP according to an exemplary embodiment of the present disclosure, the first sub-pixel SPRG having a structure in which a light emitting stack emitting red light and a light emitting stack emitting green light are stacked, and the second sub-pixel SPB having a structure in which a single light emitting stack emitting blue light is stacked is disposed.

Referring to FIG. 10A, the second sub-pixel SPB having a structure in which a single light emitting stack is stacked, includes the anode 121, the light emitting layer 122, and the cathode 123.

For example, referring to FIGS. 9 and 10A, the anode 121 is disposed on the second planarization layer 115b, the light emitting layer 122 is disposed on the anode 121 that is exposed through the open area of the bank 116, and the cathode 123 is disposed on the light emitting layer 122. Additionally, the first encapsulation layer 117a and the second encapsulation layer 117b are disposed on the cathode 123.

In contrast, referring to FIG. 10b, the first sub-pixel SPRG having a structure in which a plurality of the light emitting stacks are stacked, includes a first anode 121-1, a first light emitting layer 122-1, a cathode 123a, a second light emitting layer 122-2, and a second anode 121-2.

For example, referring to FIGS. 9 and 10B, the first anode 121-1 is disposed on the second planarization layer 115b, the light emitting stack (i.e., the first light emitting layer) 122-1 emitting red light is disposed on the first anode 121-1, and the cathode 123a is disposed on the light emitting stack 122-1 emitting red light. The light emitting stack (i.e., the second light emitting layer) 122-2 emitting green light is disposed on the cathode 123a, and the second anode 121-2 is disposed on the light emitting stack 122-2 emitting green light. At this time, the light emitting stack 122-1 emitting red light and the light emitting stack 122-2 emitting green light can share one cathode 123a. The first encapsulation layer 117a and the second encapsulation layer 117b are disposed on the second anode 121-2.

FIG. 10B illustrates the structure of the sub-pixel SPRG in which the light emitting stack 122-2 emitting green light, is disposed above the light emitting stack 122-1 emitting red light, in the first optical area DA1. However, an order in which the two light emitting stacks are stacked can be changed.

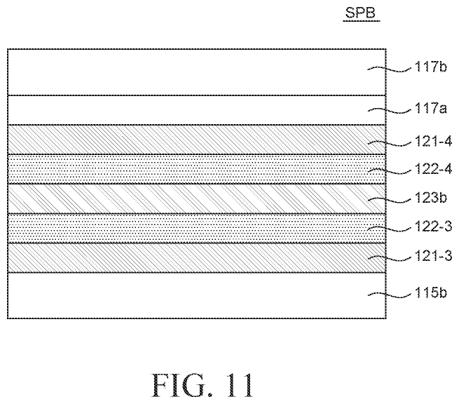

FIG. 11 is a cross-sectional view showing another example of the structure of the sub-pixel SPB in the first optical area of the display panel according to an exemplary embodiment of the present disclosure.

Previously, in FIGS. 8 to 10B, it is exemplified that a plurality of first sub-pixels SPRG having a structure in which a plurality of light emitting stacks emitting light of different colors are stacked and a plurality of second sub-pixels SPB having a structure in which a single light emitting stack is stacked are disposed in the first optical area DA1.

According to another example of the display panel DP according to an exemplary embodiment of the present disclosure, in the first optical area DA1, a plurality of first sub-pixels SPRG having a structure in which a plurality of light emitting stacks emitting light of different colors (i.e., red light and green light) as shown in FIG. 10B are stacked, and a plurality of second sub-pixels SPB having a structure in which a plurality of light emitting stacks emitting light of the same color (i.e., blue light) are stacked, can be disposed.

Referring to FIG. 11, the second sub-pixel SPB having a structure in which a plurality of light emitting stacks are stacked, includes a first anode 121-3, a first light emitting layer 122-3, a cathode 123b, a second light emitting layer 122-4, and a second anode 121-4.

For example, referring to FIGS. 9 and 11, the first anode 121-3 is disposed on the second planarization layer 115b, the light emitting stack (i.e., first light emitting layer) 122-3 emitting blue light is disposed on the first anode 121-3, and the cathode 123b is disposed on the light emitting stack 122-3 emitting blue light. The light emitting stack (i.e., the second light emitting layer) 122-4 emitting blue light is disposed on the cathode 123b, and the second anode 121-4 is disposed on the light emitting stack 122-4 emitting blue light. At this time, the light emitting stack 122-3 emitting blue light at a lower position and the light emitting stack 122-4 emitting blue light at an upper position can share one cathode 123b. The first encapsulation layer 117a and the second encapsulation layer 117b are disposed on the second anode 121-4. Through this, the number of sub-pixels disposed in the first optical area DA1 can be reduced and luminous efficiency of the second sub-pixel SPB having a structure in which a plurality of light emitting stacks emitting the same light are stacked, can be increased, so that the emission area of the sub-pixels can also be reduced. Consequently, the transmissive surface area of the transmissive areas TA1 can be further expanded.

According to still another example of the display panel DP according to an exemplary embodiment of the present disclosure, in the first sub-pixel SPRG having a structure in which a plurality of light emitting stacks emitting light of different colors disposed in the first optical area DA1 are stacked, two light emitting stacks 122-1 and 122-2 are driven by different pixel circuits. Additionally, in the second sub-pixel SPB having a structure in which a plurality of light emitting stacks emitting light of the same color are stacked, two light emitting stacks 122-3 and 122-4 are driven by the same pixel circuit.

For example, the first sub-pixel SPRG and the second sub-pixel SPB having a structure in which a plurality of light emitting stacks are stacked, can each be driven by the pixel circuit previously described with reference to FIG. 3.

Referring to FIG. 3, in the first sub-pixel SPRG having a structure in which a plurality of light emitting stacks are stacked, a first light emitting element ED including a light emitting stack EL emitting red light is connected to a first pixel circuit, so the anode electrode AE is electrically connected to the second node N2 of the driving transistor DRT and the ground voltage ELVSS is applied to the common cathode electrode CE. In addition, in the first sub-pixel SPRG having a structure in which a plurality of light emitting stacks are stacked, a second light emitting element ED including the light emitting stack EL emitting green light is connected to a second pixel circuit, so the anode electrode AE is electrically connected to the second node N2 of the driving transistor DRT and the ground voltage ELVSS is applied to the cathode electrode CE which is the common electrode.

In addition, in the second sub-pixel SPB having a structure in which a plurality of light emitting stacks are stacked, the first light emitting element ED and the second light emitting element ED each including a light emitting stack EL emitting blue light is connected in parallel to a third pixel circuit, so the anode electrode AE of each of the two light emitting elements is electrically connected to the second node N2 of the driving transistor DRT and the ground voltage ELVSS is applied to the cathode electrode CE which is the common electrode.

Meanwhile, in FIG. 9, it is illustrated that the transistors are disposed below the light emitting element 120 in an area where the blue sub-pixel SPB is disposed (i.e., the emission area) in the first optical area DA1.

In the display panel DP according to another exemplary embodiment of the present disclosure, a transistor for driving the sub-pixel is disposed in an outer portion of the first optical area DA1 other than in the emission area and transmissive area of the first optical area DA1, so that the transmissive surface area of the transmissive areas can be substantially improved to a greater extent.

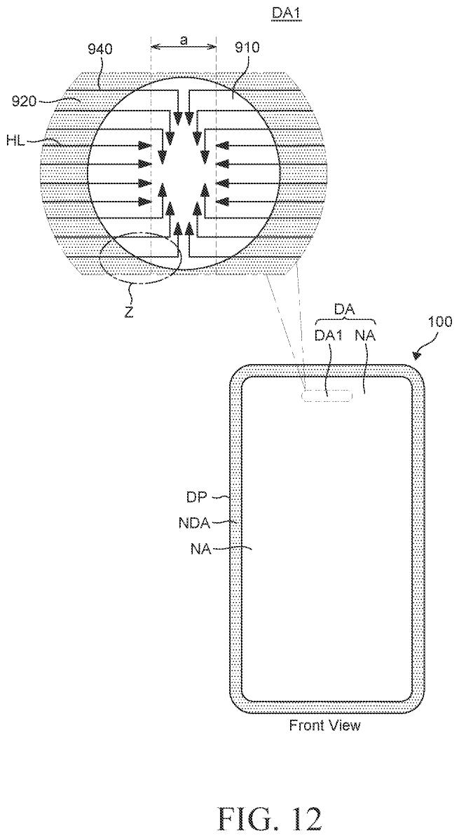

Hereinafter, with reference to FIGS. 12 to 16, an arrangement structure of the pixel circuit for driving the sub-pixels disposed in the first optical area DA1 of the organic light emitting display apparatus 100 according to another exemplary embodiment of the present disclosure will be described in detail.

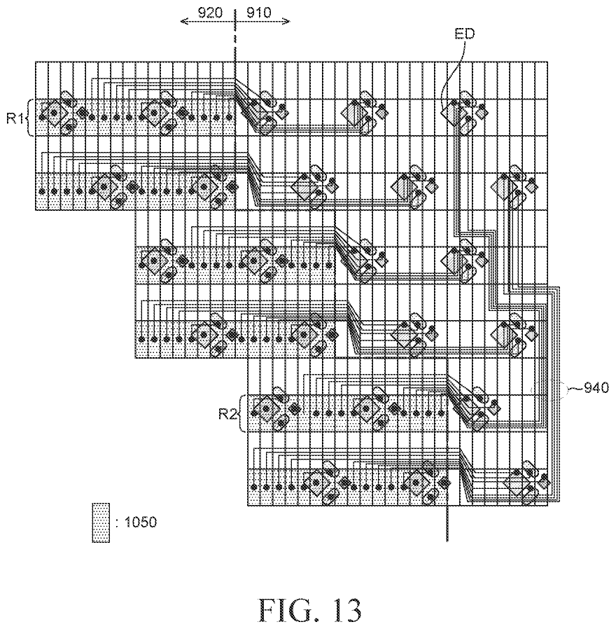

FIG. 12 is an enlarged plan view of a first optical area in a display panel of an organic light emitting display apparatus according to another exemplary embodiment of the present disclosure. FIG. 13 is an enlarged plan view of area Z of FIG. 12.

Referring to FIG. 12, in the display panel DP of the organic light emitting display apparatus 100 according to another exemplary embodiment of the present disclosure, the first optical area DA1 can include a central area 910 and a bezel area 920 located on an outside of the central area 910. At this time, the bezel area 920 can be located at a boundary area between the first optical area DA1 and the normal area NA and surround the first optical area DA1 (e.g., the bezel area 920 can be an outer edge area surrounding the central area 910). Additionally, pixel circuits, for example, transistors, for driving each of the plurality of sub-pixels disposed in the first optical area DA1 can be disposed in the bezel area 920.

The first optical area DA1 can include a plurality of horizontal lines HL. The transistor located in the bezel area 920 and light emitting elements located in the central area 910 can be connected by the plurality of horizontal lines HL.

The organic light emitting display apparatus 100 according to another exemplary embodiment of the present disclosure can include a routing structure 940. By including the routing structure 940, the central area 910 can be expanded by a predetermined area (a).

Referring to FIG. 13, the first optical area DA1 can display a screen by including a plurality of light emitting elements ED located in the central area 910 and the bezel area 920.

In addition, the first optical area DA1 includes a plurality of transistors 1050 located in the bezel area 920, and the transistors 1050 may not be located in the central area 910.

The first optical area DA1 can include a plurality of rows including a first row R1 and a second row R2. The plurality of rows included in the first optical area DA1 are arbitrary areas crossing the first optical area DA1 in a horizontal direction and can be defined by patterns of the transistors 1050.

The organic light emitting display apparatus 100 according to another exemplary embodiment of the present disclosure can include the light emitting elements ED located in the central area 910 of the first optical area DA1 and located in the first row R1, the transistors 1050 located in the bezel area 920 and located in the second row R2, and the routing structure 940 electrically connecting the light emitting elements ED located in the first row R1 and the transistors 1050 located in the second row R2.

By the routing structure 940, the transistors 1050 and the light emitting elements ED located in different rows can be connected. The routing structure 940 can include a plurality of transparent lines.

The number of light emitting elements ED disposed in the first row R1 of the central area 910 can be greater than the number of light emitting elements ED disposed in the second row R2 of the center area 920. Therefore, a relatively large number of the transistors 1050 are required to drive the light emitting elements ED included in the first row R1, and a relatively small number of the transistors 1050 are required to drive the light emitting elements ED included in the second row R2. Accordingly, among the transistors 1050 located in the second row R2 of the bezel area 920, surplus transistors 1050 that are not electrically connected to the light emitting elements ED located in the second row R2 can be electrically connected to the light emitting elements ED located in the first row R1 through the routing structure 940.

The number of the sub-pixels SP included per unit area in an entirety of the central area 910 can be substantially the same. This can mean that one pixel pattern is substantially uniform in the entirety of the central area 910.

Since an area overlapping the center region 910 is larger in the first row R1 than in the second row R2, a relatively greater number of the light emitting elements ED can be located in the first row R1. In addition, the number of the transistors 1050 included in the first row R1 of the bezel area 920 can be substantially equal to the number of the transistors 1050 included in the second row R2 of the bezel area 920. In this case, if the number of the light emitting elements ED included in the first row R1 in the central area 910 is greater, and the number of the light emitting elements ED included in the second row R2 in the central area 910 is smaller, some of the transistors 1050 included in the second row R2 can be electrically connected to the light emitting elements ED located in the first row R1 other than the second row R2.

The number of the transistors 1050 included per unit area in the entirety of the bezel area 920 can be substantially the same. This can mean that one transistor pattern is substantially uniform in the entirety of the bezel area 920.

An area of the bezel area 920 overlapping the first row R1 can be substantially the same as an area of the bezel area 920 overlapping the second row R2. In this case, the number of the transistors 1050 located in the first row R1 of the bezel area 920 can be substantially the same as the number of the transistors 1050 located in the second row R2 of the bezel area. Accordingly, the number of the transistors 1050 located in each row of the bezel area 920 can be maintained constant, and the routing structure 940 can allow surplus transistors in a specific row to be electrically connected to surplus light emitting elements in other rows.

In this manner, by applying a structure of the first optical area DA1 of the organic light emitting display apparatus 100 according to another exemplary embodiment of the present disclosure described with reference to FIGS. 12 and 13, a structure in which the first sub-pixel SPRG and the second sub-pixel SPB disposed in the first optical area DA1 described above with reference to FIGS. 8 to 12 are connected to the transistors disposed in the bezel area 920 will be described.

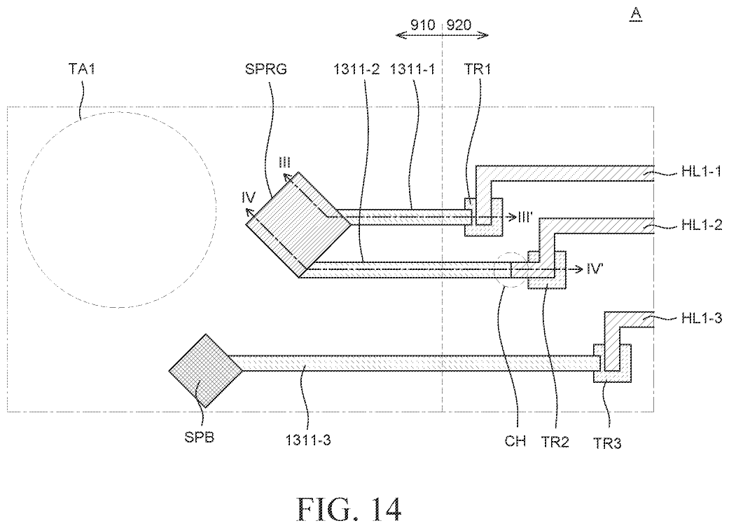

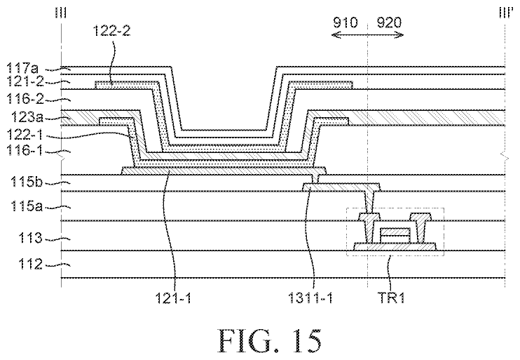

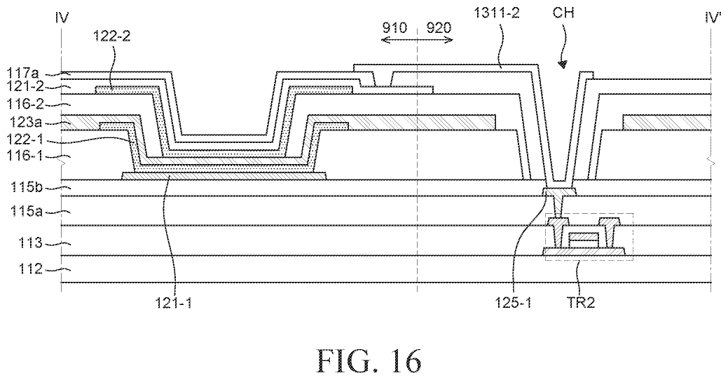

FIG. 14 is a schematic enlarged plan view illustrating area A of FIG. 8. FIG. 15 is a cross-sectional view taken along line III-III′ of FIG. 14. FIG. 16 is a cross-sectional view taken along line IV-IV′ of FIG. 14.

In FIG. 14, area A shown in FIG. 8 is enlarged and illustrated, and in this case, the first sub-pixel SPRG and the second sub-pixel SPB, and the transmissive area TA1 that are disposed in an outermost area of the central area 910 of the first optical area DA1, for example, near the bezel area 920 are illustrated.

The second sub-pixel SPB shown in FIG. 14 can have a structure in which a single light emitting stack emitting blue light is stacked, or a structure in which a plurality of light emitting stacks emitting blue light are stacked. At this time, the second sub-pixel SPB disposed in the central area 910 of the first optical area DA1 is connected to a transistor TR3 disposed in the bezel area 920 through a transparent line 1311-3 of the routing structure 940. The transistor TR3 can be connected to a gate line HL1-3 and can also be connected to a data line VL1.

Meanwhile, the first sub-pixel SPRG shown in FIG. 14 has a structure in which a first light emitting stack emitting red light and a second light emitting stack emitting green light are stacked. At this time, in the first sub-pixel SPRG disposed in the central area 910 of the first optical area DA1, a first anode that is connected to the first light emitting stack (i.e., light emitting layer) is connected to a transistor TR1 disposed in the bezel area 920 through a transparent line 1311-1. In addition, in the first sub-pixel SPRG disposed in the central area 910 of the first optical area DA1, a second anode that is connected to the second light emitting stack (i.e., light emitting layer) is connected to a transistor TR2 disposed in the bezel area 920 through a transparent line 1311-2. The transistor TR1 can be connected to a gate line HL1-1, and the transistor TR2 can be connected to a gate line HL1-2. The transistor TR1 and the transistor TR2 can be connected to different data lines VL1, respectively.

FIGS. 15 and 16 show schematic cross-sectional views of structures in which the first sub-pixel SPRG disposed in the central area 910 of the first optical area DA1 is connected to the transistors TR1 and TR2 disposed in the bezel area 920 through the transparent lines 1311-1 and 1311-2 of the routing structure 940.

FIGS. 15 and 16 mainly show connection relationships between the first and second light emitting stacks of the first sub-pixel SPRG and the transistors. For convenience of explanation, a detailed description regarding components the same as the substrate SUB, the transistor layer TRL, the planarization layer PLN, the light emitting element layer EDL, the encapsulation layer ENCAP, the touch sensing layer TSL, and the protective layer PAC in the first optical area DA1, previously described with reference to FIG. 9 will be omitted.

In addition, each of the transistor TR1 and the transistor TR2 connected to each of light emitting stack structures of the first sub-pixel SPRG shown in FIGS. 15 and 16 can be the driving transistor Td disposed in the transistor layer TRL previously described in FIG. 9, and for convenience of explanation, redundant descriptions will be omitted. In addition, in the bezel area 920, in addition to the transistor TR1 and the transistor TR2 that are electrically connected to the first sub-pixel SPRG, the switching transistor Ts as shown in FIG. 9 can be disposed in plural for driving of the first sub-pixel SPRG.

Referring to FIGS. 14 and 15, in the first sub-pixel SPRG disposed in the central area 910 of the first optical area DA1, the first anode 121-1 is disposed on the second planarization layer 115b, the light emitting stack (i.e., first light emitting layer) 122-1 emitting red light is disposed on the first anode 121-1, and the common cathode 123a is disposed on the light emitting stack 122-1 emitting red light.

A first bank 116-1 is disposed on the second planarization layer 115b to cover the first anode 121-1, and a portion of the first bank 116-1 corresponding to an emission area of the first sub-pixel SPRG can be opened. For example, the anode 121 is exposed to the open area of the first bank 116-1.

A second bank 116-2 is disposed on the common cathode 123a to cover the common cathode 123a, and a portion of the second bank 116-2 corresponding to the emission area of the first sub-pixel SPRG can be opened. For example, the common cathode 123a is exposed to the open area of the second bank 116-2.

The light emitting stack (i.e., the second light emitting layer) 122-2 emitting green light is disposed on the common cathode 123a, and the second anode 121-2 is disposed on the light emitting stack 122-2 emitting green light. The first encapsulation layer 117a is disposed on the second anode 121-2.

The transparent line 1311-1 is disposed on the first planarization layer 115a to extend from the central area 910 to the bezel area 920. One end of the transparent line 1311-1 is electrically connected to either a source electrode or a drain electrode of the transistor TR1 disposed on the interlayer insulating layer 113 through a contact hole provided in the first planarization layer 115a in the bezel area 920. The other end of the transparent line 1311-1 is electrically connected to the first anode 121-1 disposed below the first sub-pixel SPRG through a contact hole provided in the second planarization layer 115b in the central area 910.

Through this structure, the first light emitting stack 122-1 of the first sub-pixel SPRG disposed in the central area 910 and the transistor TR1 disposed in the bezel area 920 are electrically connected.

Referring to FIGS. 14 and 16, the transparent line 1311-2 is disposed on the first encapsulation layer 117a to extend from the central area 910 to the bezel area 920.

One end of the transparent line 1311-1 is electrically connected to a connection electrode 125-1 disposed on the first planarization layer 115a through contact holes CH provided in the first planarization layer 117a and the banks 116-1 and 116-2 in the bezel area 920. The connection electrode 125-1 is electrically connected to either a source electrode or a drain electrode of the transistor TR2 disposed on the interlayer insulating layer 113 through a contact hole provided in the first planarization layer 115a in the bezel area 920. The other end of the transparent line 1311-1 is electrically connected to the second anode 121-2 disposed in an upper portion of the first sub-pixel SPRG through a contact hole provided in the first encapsulation layer 117a in the central area 910.

Through this structure, the second light emitting stack 122-2 of the first sub-pixel SPRG disposed in the central area 910 and the transistor TR2 disposed in the bezel area 920 are electrically connected.

Connection structures of the first sub-pixel SPRG and the transistors described with reference to FIGS. 15 and 16 can also be applied to the second sub-pixel SPB having a structure in which a plurality of light emitting stacks emitting light of the same color are stacked, for the same purpose.

In addition, even in the case of the sub-pixel SPB having a structure in which a single light emitting stack is stacked, a connection structure of the first anode 121-1 and the transistor TR1 of the first sub-pixel SPRG shown in FIG. 15 can also be applied for the same purpose. As described above, in the display panel DP according to another exemplary embodiment of the present disclosure, by disposing transistors for driving the sub-pixels SP in the bezel area 920 outside the first optical area DA1, other than the emission areas and the transmissive areas of the first optical area DA1, the transmissive surface area of the transmissive areas can be substantially improved to a greater extent.

Some aspects of the exemplary embodiments of the present disclosure can also be described as follows:

According to an aspect of the present disclosure, there is provided an organic light emitting display. The organic light emitting display includes a substrate including a first display area having a plurality of sub-pixels disposed therein and including emission areas and transmissive areas, and a second display area surrounding the first display area. The organic light emitting display further includes a plurality of transistors located on the substrate and electrically connected to the plurality of sub-pixels. The plurality of sub-pixels include a plurality of first sub-pixels disposed in the emission areas of the first display area and having a structure in which a plurality of light emitting stacks emitting light of different colors are stacked.

The plurality of sub-pixels can further include a plurality of second sub-pixels disposed in the emission areas of the first display area and having a structure in which a single light emitting stack is stacked.

The plurality of first sub-pixels and the plurality of second sub-pixels can emit light of different colors.

The plurality of first sub-pixels can have a structure in which a first light emitting stack emitting red light and a second light emitting stack emitting green light are stacked. The plurality of second sub-pixels can include a third light emitting stack emitting blue light.

A pixel circuit for driving the first light emitting stack and a pixel circuit for driving the second light emitting stack can be different from each other.

The plurality of first sub-pixels can have a structure in which a first anode, the first light emitting stack, a cathode, the second light emitting stack, and a second anode are stacked.

The plurality of sub-pixels can further include a plurality of second sub-pixels disposed in the emission areas of the first display area and having a structure in which a plurality of emission stacks emitting light of the same color are stacked.

The plurality of first sub-pixels can have a structure in which a first light emitting stack emitting red light and a second light emitting stack emitting green light are stacked. The plurality of second sub-pixels can include a third light emitting stack emitting blue light and a fourth light emitting stack emitting blue light.

A pixel circuit for driving the first light emitting stack and a pixel circuit for driving the second light emitting stack can be different from each other. A pixel circuit for driving the third light emitting stack and a pixel circuit for driving the fourth light emitting stack can be identical to each other.

The plurality of first sub-pixels can have a structure in which a first anode, the first light emitting stack, a cathode, the second light emitting stack, and a second anode are stacked. The plurality of second sub-pixels can have a structure in which a third anode, the third light emitting stack, a cathode, the fourth light emitting stack, and a fourth anode are stacked.

The substrate can further include a bezel area surrounding the first display area between the first display area and the second display area. The plurality of transistors can be disposed only in the second display area and the bezel area.

A transistor disposed in the bezel area among the plurality of transistors can be connected to at least one of the plurality of sub-pixels disposed in the first display area.

The organic light emitting display apparatus can further include a transparent line connecting the transistor disposed in the bezel area and at least one of the plurality of sub-pixels disposed in the first display area.

The plurality of sub-pixels can further include a third sub-pixel, a fourth sub-pixel, and a fifth sub-pixel disposed in the second display area and emitting light of different colors and each having a single light emission stack.

A cathode disposed in the first display area can be disposed only in the emission area among the emission area and the transmissive area.

The organic light emitting display apparatus can further include an optical electronic device disposed below the substrate in the first display area.

The number of sub-pixels per unit area in the first display area can be less than the number of sub-pixels per unit area in the second display area.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto.

Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. An organic light emitting display apparatus, comprising:
a substrate including a first display area and a second display area adjacent to the first display area, the first display area including emission areas and transmissive areas;
a plurality of sub-pixels disposed in the first display area; and
a plurality of transistors disposed on the substrate and electrically connected to the plurality of sub-pixels,
wherein the plurality of sub-pixels include a plurality of first sub-pixels disposed in the emission areas of the first display area and having a structure in which a plurality of light emitting stacks configured to emit light of different colors are stacked.

2. The organic light emitting display apparatus of claim 1, wherein the plurality of sub-pixels further include a plurality of second sub-pixels disposed in the emission areas of the first display area and having a structure in which a single light emitting stack is stacked.

3. The organic light emitting display apparatus of claim 2, wherein the plurality of first sub-pixels and the plurality of second sub-pixels are configured to emit light of different colors.

4. The organic light emitting display apparatus of claim 2, wherein the plurality of first sub-pixels have a structure in which a first light emitting stack configured to emit red light and a second light emitting stack configured to emit green light are stacked, and
wherein the plurality of second sub-pixels include a third light emitting stack configured to emit blue light.

5. The organic light emitting display apparatus of claim 4, wherein a pixel circuit configured to drive the first light emitting stack and a pixel circuit configured to drive the second light emitting stack are different from each other.

6. The organic light emitting display apparatus of claim 4, wherein the plurality of first sub-pixels have a structure in which a first anode, the first light emitting stack, a cathode, the second light emitting stack, and a second anode are stacked.

7. The organic light emitting display apparatus of claim 1, wherein the plurality of sub-pixels further include a plurality of second sub-pixels disposed in the emission areas of the first display area and having a structure in which a plurality of emission stacks configured to emit light of a same color are stacked.

8. The organic light emitting display apparatus of claim 7, wherein the plurality of first sub-pixels have a structure in which a first light emitting stack configured to emit red light and a second light emitting stack configured to emit green light are stacked, and
wherein the plurality of second sub-pixels include a third light emitting stack configured to emit blue light and a fourth light emitting stack configured to emit blue light.

9. The organic light emitting display apparatus of claim 8, wherein a pixel circuit configured to drive the first light emitting stack and a pixel circuit configured to drive the second light emitting stack are different from each other, and
wherein a pixel circuit configured to drive the third light emitting stack and a pixel circuit configured to drive the fourth light emitting stack are identical to each other.

10. The organic light emitting display apparatus of claim 8, wherein the plurality of first sub-pixels have a structure in which a first anode, the first light emitting stack, a cathode, the second light emitting stack, and a second anode are stacked, and
wherein the plurality of second sub-pixels have a structure in which a third anode, the third light emitting stack, a cathode, the fourth light emitting stack, and a fourth anode are stacked.

11. The organic light emitting display apparatus of claim 1, wherein the substrate further includes a bezel area adjacent to the first display area and disposed between the first display area and the second display area, and
wherein the plurality of transistors are disposed only in the second display area and the bezel area.

12. The organic light emitting display apparatus of claim 11, wherein one of the plurality of transistors that is disposed in the bezel area is connected to at least one of the plurality of sub-pixels disposed in the first display area.

13. The organic light emitting display apparatus of claim 12, further comprising:
a transparent line connecting the one of the plurality of transistors that is disposed in the bezel area and at least one of the plurality of sub-pixels disposed in the first display area.

14. The organic light emitting display apparatus of claim 1, wherein the plurality of sub-pixels further include a third sub-pixel, a fourth sub-pixel, and a fifth sub-pixel disposed in the second display area and configured to emit light of different colors, and
each of the third sub-pixel, the fourth sub-pixel, and the fifth sub-pixel has a single light emission stack.

15. The organic light emitting display apparatus of claim 1, wherein a cathode disposed in the first display area is disposed only in the emission area among the emission areas and the transmissive areas.

16. The organic light emitting display apparatus of claim 1, further comprising:
an optical electronic device disposed below the substrate in the first display area.

17. The organic light emitting display apparatus of claim 1, wherein a number of sub-pixels per unit area in the first display area is less than a number of sub-pixels per unit area in the second display area.
